(19) United States
(12) Patent Application Publication
(10) Pub. No.: US 2017/0112024 A1
(43) Pub. Date: Apr. 20, 2017

(54) SHELF APPARATUS AND METHOD OF MANUFACTURING SHELF APPARATUS

(71) Applicant: FUJITSU LIMITED, Kawasaki-shi (JP)

(72) Inventor: Yoshiyuki Sato, Yokohama (JP)

(73) Assignee: FUJITSU LIMITED, Kawasaki-shi (JP)

(21) Appl. No.: 15/245,665

(22) Filed: Aug. 24, 2016

(30) Foreign Application Priority Data
Oct. 15, 2015 (JP) 2015-203833

(51) Int. Cl. H05K 7/20; H05K 7/14

(52) U.S. Cl. CPC H05K 7/20581; H05K 7/20145; H05K 7/20172; H05K 7/1417; H05K 7/14

(57) ABSTRACT

A shelf apparatus includes a body that includes a first opening provided in a top surface, a second opening provided in a bottom surface, and a back plane that includes a first and a second terminals; a first air-cooling device that is attachable to the top surface and includes a first substrate, a first fan, and a first connector configured to couple the first substrate to the back plane, wherein the first terminal is coupled to the first connector inserted into the first opening; a second air-cooling device that is attachable to the bottom surface and includes a second substrate, a second fan, and a second connector configured to couple the second substrate to the back plane, wherein the second terminal is coupled to the second connector inserted into the second opening; and an air guide device that is attachable to a bottom surface of the second air-cooling device.

### CROSS-REFERENCE TO RELATED APPLICATION

This application is based upon and claims the benefit of priority of the prior Japanese Patent Application No. 2015-203833, filed on Oct. 15, 2015, the entire contents of which are incorporated herein by reference.

### FIELD

The embodiments discussed herein are related to a shelf apparatus and a method of manufacturing a shelf apparatus.

### BACKGROUND

Some types of conventional electronic apparatuses, such as optical transmission apparatuses or network apparatuses, include plug-in unit mounting sections (also referred to as sub-racks) which are stacked and mounted in a 19 or 23 inches-wide rack. In each plug-in unit mounting section, plural plug-in units are mounted. Each plug-in unit includes a printed board unit which includes electronic components mounted thereon and has a predetermined function. The printed board unit is plug-in connected through a connector to a backboard, which is provided in the plug-in unit mounting section. The plug-in units are detachably attached to the backboard. Since components that generate heat are mounted on the plug-in units, the plug-in unit mounting sections are cooled by cooling wind coming from forced air-cooling devices. The forced air-cooling devices are installed above and below the plug-in unit mounting section. A method of sending cooling wind upward from the bottom for heat dissipation is mainly used in the forced air-cooling devices. Herein, the mode including the plug-in unit mounting section and the forced air-cooling devices attached thereto is referred to as a shelf apparatus.

First, a description is given of the structure of a shelf apparatus S0 for plug-in units as a comparative example with reference to FIGS. 1A and 1B. Hereinafter, the side of the shelf apparatus S0 into and from which plug-in units 8 are inserted and removed is referred to as a front side of the shelf apparatus S0, and the opposite side is referred to as a back side. FIG. 1A is a front-right perspective view of the shelf apparatus S0. In FIG. 1A, one of the plug-in units 8, one of pull-fan units 12, and one of push-fan units 22 are detached from the shelf apparatus S0. The pull-fan units 12 are air-cooling devices having a function of sucking the cooling wind. The push-fan units 22 are air-cooling devices having a function of blowing out cooling wind. FIG. 1B is a rear-left perspective view of the shelf apparatus S0 illustrated in FIG. 1A. In FIG. 1B, similarly, one of the plug-in units 8, one of the pull-fan units 12, and one of the push-fan units 22 are detached from the shelf apparatus S0.

Each of the plug-in units 8 includes a circuit board 80. The circuit board 80 is provided with a panel 81 and a lock mechanism 82 on the front side thereof. On the back side of the plug-in unit 8, an attachment connector 83 is provided. The attachment connector 83 is coupled to a back plane (described later), which is located within the back side of the shelf apparatus S0. On the circuit board 80, electronic components are mounted. FIG. 1A does not illustrate the mounted electronic components. The shelf apparatus S0 accommodates the plural plug-in units 8 vertically stood in parallel to each other on the front side of a body section 5A. When the plug-in units 8 are inserted into the shelf apparatus S0, the plug-in units 8 are locked to the body section 5A with the lock mechanism 82.

Below the plug-in units 8 mounted in the body section 5A, a lower cooling device 2A is provided. The lower cooling device 2A sends cooling wind to forcedly cool the plug-in units 8. The lower cooling device 2A includes the three push-fan units 22 arranged side by side in this example. Each of the push-fan units 22 includes three fans 21 blowing air upward. Each push-fan unit 22 is provided with an attachment connector 23 which is coupled to the back plane provided within the shelf apparatus S0. Below the lower cooling device 2A, an air guide device 4A is provided. The air guide device 4A includes a baffle (heat baffle) to take in the cooling wind from the front side of the shelf apparatus S0 and direct the wind upward. In upper part of the body section 5A, an upper cooling device 1A is provided to discharge toward the back of the body section 5A, the cooling wind which has been sent upward from the lower cooling device 2A and has cooled the plug-in units 8. In the upper cooling device 1A of the comparative technique, the three pull-fan units 12, each of which includes two fans 11, are arranged side by side. The thus-configured shelf apparatus S0 is mounted on a not-illustrated rack for use with attachment flanges 5F provided on right and left side surfaces of the body section 5A.

FIG. 2 is a vertical-sectional view of the shelf apparatus S0 illustrated in FIGS. 1A and 1B. The structure of the shelf apparatus S0 is described in more detail using FIG. 2. The air guide device 4A located at the bottom of the body section 5A is opened on the front side of the body section 5A and includes a baffle 47 to direct upward the flow of cooling wind W taken inside. The lower cooling device 2A provided on the air guide device 4A includes the push-fan units 22 each including the three fans 21. The fans 21 send the cooling wind W toward the plug-in units 8. The push-fan units 22 are attached to a back plane 58A through the respective attachment connectors 23. The cooling wind W taken into the body section 5A through the opening of the air guide device 4A is directed upward by the baffle 47 and is sent to the lower cooling device 2A. In the lower cooling device 2A, the push-fan units 22 send the cooling wind W toward the plug-in units 8, so that the plug-in units 8 are cooled by the cooling wind W.

The back plane 58A as a backboard is provided within the back side of the body section 5A. The lower part of the back plane 58A extends to the lower cooling device 2A. The back plane 58A is coupled to the push-fan units 22 through the attachment connectors 23 and supply power to the push-fan units 22. The back plane 58A is also used to, for example, detect failure of fan motors. At the center of the back plane 58A, plural attachment connectors 53 are provided. The attachment connectors 53 are fit to the respective attachment connectors 83 of the plug-in units 8. Moreover, upper part of the back plane 58A extends to the upper cooling device 1A. The back plane 58A is coupled to the pull-fan units 12 through the attachment connectors 13 and supplies power source to the pull-fan units 12. The cooling wind W having cooled the plug-in units 8 changes the direction due to a baffle 17 of the upper cooling device 1A to be discharged out of the body section 5A by the pull-fan units 12. As the related art thereto, Japanese Laid-open Patent Publications Nos. 2007-324238 and 2010-232474 are disclosed, for example.

When plug-in units which generate a small amount of heat are installed in the shelf apparatus of the comparative example, for example, the cooling by the upper and lower cooling devices is too much, and the shelf apparatus requests any one of the cooling devices. In this case, a shelf apparatus including one cooling device is developed. When a short-height shelf apparatus is desired, a shelf apparatus provided with no air guide device is developed. In this case, the bottom surface of the lower cooling device is configured as the inlet of the cooling wind. Moreover, when a shelf apparatus requests to include plural body sections, the shelf apparatus is provided with an intermediate cooling device between the upper and lower cooling devices. As described above, according to the comparative example, individual shelf apparatuses have to be developed according to client's request specifications. The comparative example involves problems of high design cost, high manufacturing cost, and long manufacturing lead time. It is preferable that shelf apparatuses different in request specifications do not request to be individually developed and be manufactured at lower cost.

### SUMMARY

According to an aspect of the invention, a shelf apparatus includes a body that includes a first opening provided in a top surface of the body, a second opening provided in a bottom surface of the body, and a back plane that is provided on a back side of the body and includes a first terminal and a second terminal, wherein at least one plug-in unit is capable of being detachably attached to the back plane; a first air-cooling device that is attachable to the top surface of the body and includes a first substrate, a first fan coupled to the first substrate and discharges cooling wind to the back side of the body, and a first connector configured to couple the first substrate to the back plane, wherein the first terminal is coupled to the first connector inserted into the first opening; a second air-cooling device that is attachable to the bottom surface of the body and includes a second substrate, a second fan coupled to the second substrate and sends the cooling wind toward the at least one plug-in unit, and a second connector configured to couple the second substrate to the back plane, wherein the second terminal is coupled to the second connector inserted into the second opening; and an air guide device that is attachable to a bottom surface of the second air-cooling device and includes a baffle configured to direct the cooling wind taken in from a front side of the body toward the second air-cooling device.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a front-right perspective view of a shelf apparatus for plug-in units of a comparative example;

FIG. 1B is a rear-left perspective view of the shelf apparatus illustrated in FIG. 1A;

FIG. 2 is a vertical-sectional view of the shelf apparatus illustrated in FIGS. 1A and 1B;

FIG. 3A is a front-right perspective view of a shelf apparatus for plug-in units of a first embodiment of the disclosure;

FIG. 3B is a rear-left perspective view of the shelf apparatus illustrated in FIG. 3A;

FIG. 4 is an exploded perspective view of the shelf apparatus illustrated in FIG. 3A;

FIG. 5 is an exploded cross-sectional view of the shelf apparatus illustrated in FIG. 3A;

FIG. 6A is a rear-left perspective view of the body of a shelf apparatus for plug-in units according to a second embodiment of the disclosure;

FIG. 6B is a main part enlarged view illustrating a part around a through-hole for insertion of a first connector which is provided in the body illustrated in FIG. 6A;

FIG. 7A is an inner view of s part around the through-hole illustrated in FIG. 6B as seen from the inside of the body;

FIG. 7B is a rear perspective view of a slide member incorporated in a closing plate lock mechanism illustrated in FIG. 7A;

FIG. 7C is a front perspective view of the slide member illustrated in FIG. 7B;

FIG. 7D is a cross-sectional view taken along a line D-D of FIG. 7A;

FIG. 7E is a cross-sectional view taken along a line E-E of FIG. 7A;

FIG. 8A is a rear-bottom perspective view of a first air-cooling device of a second embodiment;

FIG. 8B is a partial enlarged perspective view of a first connector provided in the first air-cooling device illustrated in FIG. 8A;

FIG. 9A is a cross-sectional view of the first connector illustrated in FIG. 8B;

FIG. 9B is a partial enlarged perspective view illustrating the state where the closing plate which closes the through-hole as illustrated in FIG. 6B is opened by the first connector;

FIG. 9C is a partial view illustrating a terminal section of the back plane located within the through-hole illustrated in FIG. 9B, the terminal section being coupled to the first connector;

FIG. 10A is a partial enlarged cross-sectional view illustrating the state where the first connector illustrated in FIG. 8B has come close to the through-hole illustrated in FIG. 6B in the process of attaching the first air-cooling device to the body;

FIG. 10B is a partial enlarged cross-sectional view illustrating the state where the first connector illustrated in FIG. 10A presses and opens the closing plate for the through-hole;

FIG. 10C is a partial enlarged cross-sectional view illustrating the state where the first air-cooling device is attached to the body and the first connector is coupled to the back plane within the body;

FIG. 11A is a vertical sectional view of the shelf apparatus of the second embodiment;

FIG. 11B is a partial enlarged cross-sectional view of part B of FIG. 11A;

FIG. 11C is a partial enlarged cross-sectional view of part C of FIG. 11A;

FIG. 12A is a rear-left perspective view of the body of the shelf apparatus for plug-in units according to a third embodiment of the disclosure;

FIG. 12B is a main part enlarged view illustrating a part around the through-hole for insertion of the first connector provided in the body illustrated in FIG. 12A;

FIG. 13A is a rear-bottom perspective view of a first air-cooling device of the third embodiment;

FIG. 13B is a partial enlarged perspective view of a part around the first connector in the first air-cooling device illustrated in FIG. 13A;

FIG. 14A is an inside view of the through-hole illustrated in FIG. 12B, as seen from the inside of the body;

FIG. 14B is a top perspective view of a slide member used in the mechanism to lock the closing plate according to the third embodiment;

FIG. 14C is a bottom perspective view of the slide member illustrated in FIG. 14B;

FIG. 15 is a partial enlarged cross-sectional view illustrating the state where the first connector has come close to the through-hole in the process of attaching the first air-cooling device to the body, the cross-sectional view being taken along a line A-A of FIG. 14A;

FIG. 16A is a partial enlarged cross-sectional view illustrating the state where the first air-cooling device has further approached the body from the state illustrated in FIG. 15 and the guide pin has released the lock of the closing plate lock mechanism;

FIG. 16B is a partial enlarged cross-sectional view illustrating the state where the first air-cooling device is combined with the body from the state illustrated in FIG. 16A;

FIG. 17A is a partial enlarged cross-sectional view of the state illustrated in FIG. 14A, as seen transversely;

FIG. 17B is a partial enlarged cross-sectional view illustrating the state where the first air-cooling device has further approached the body from the state illustrated in FIG. 17A and the first connector presses and opens the closing plate for the through-hole;

FIG. 17C is a partial enlarged cross-sectional view illustrating the state where the first air-cooling device is attached to the body and the first connector is coupled to the back plane within the body;

FIG. 18A is a partial enlarged cross-sectional view illustrating the state where the guide pin is approaching a guide hole;

FIG. 18B is a partial enlarged cross-sectional view illustrating the state where the tip of the guide pin is inserted into the guide hole to come into contact with a tapered hole of the slide member;

FIG. 18C is a partial enlarged cross-sectional view illustrating the state where the tip of the guide pin is further inserted into the guide hole and presses the slope of the tapered hole of the slide member to slide the slide member transversely;

FIG. 18D is a partial enlarged cross-sectional view illustrating the state where the tip of the guide pin is still further inserted into the guide hole and enters an operation hole of the slide member and the slide member has finished sliding transversely;

FIG. 19 is a perspective view illustrating the structure of an example of a joint device used to combine the bodies in the shelf apparatus;

FIG. 20 is a cross-sectional view illustrating the structure of a third air-cooling device used to combine the bodies in the shelf apparatus;

FIG. 21A is an exploded side view illustrating a shelf apparatus according to a fourth embodiment of the disclosure, in which two bodies are combined through a connector plate;

FIG. 21B is an exploded side view illustrating a shelf apparatus according to a fifth embodiment of the disclosure, in which two bodies are combined through a third air-cooling device including connectors at the top and bottom;

FIG. 22 is a front perspective view of a shelf apparatus according to a sixth embodiment, the shelf apparatus in which two shelf apparatuses according to any one of the first to third embodiments illustrated in FIGS. 3A to 18D are mounted in a rack;

FIG. 23A is a front right perspective view of a usage example of a 23 inches-wide shelf apparatus which includes one body and is transversely situated;

FIG. 23B is a front left perspective view of the shelf apparatus illustrated in FIG. 23A;

FIG. 24A is a front right perspective view of a usage example of a 19 inches-wide shelf apparatus which includes one body and is transversely situated;

FIG. 24B is a front left perspective view of the shelf apparatus illustrated in FIG. 24A;

FIG. 25A is a schematic front view of the shelf apparatus illustrated in FIG. 24A;

FIG. 25B is a schematic front view of a shelf apparatus according to a seventh embodiment which includes the shelf apparatus illustrated in FIG. 25A and a second air-cooling device attached to the exhaust side thereof;

FIG. 25C is a schematic front view of a shelf apparatus of an eighth embodiment which includes: two bodies transversely situated and horizontally coupled with a connector plate; and second air-cooling devices on both sides; and

FIG. 25D is a schematic front view of a shelf apparatus of a ninth embodiment which includes: two bodies transversely situated and horizontally coupled with the third air-cooling device including the first and second connectors; and second air-cooling devices on both sides.

### DESCRIPTION OF EMBODIMENTS

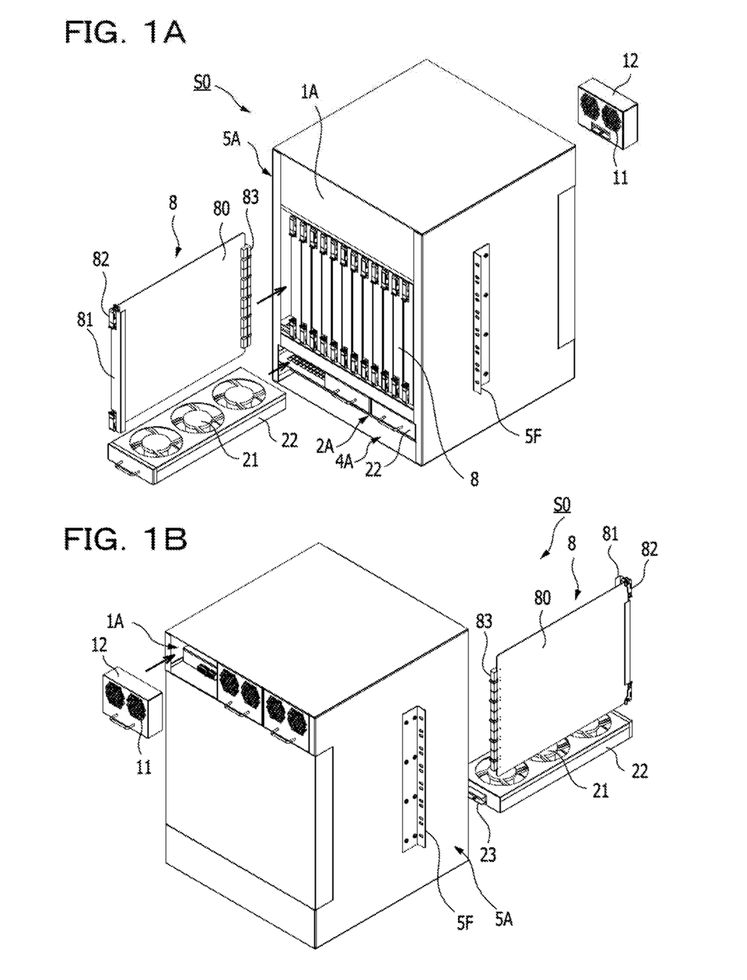

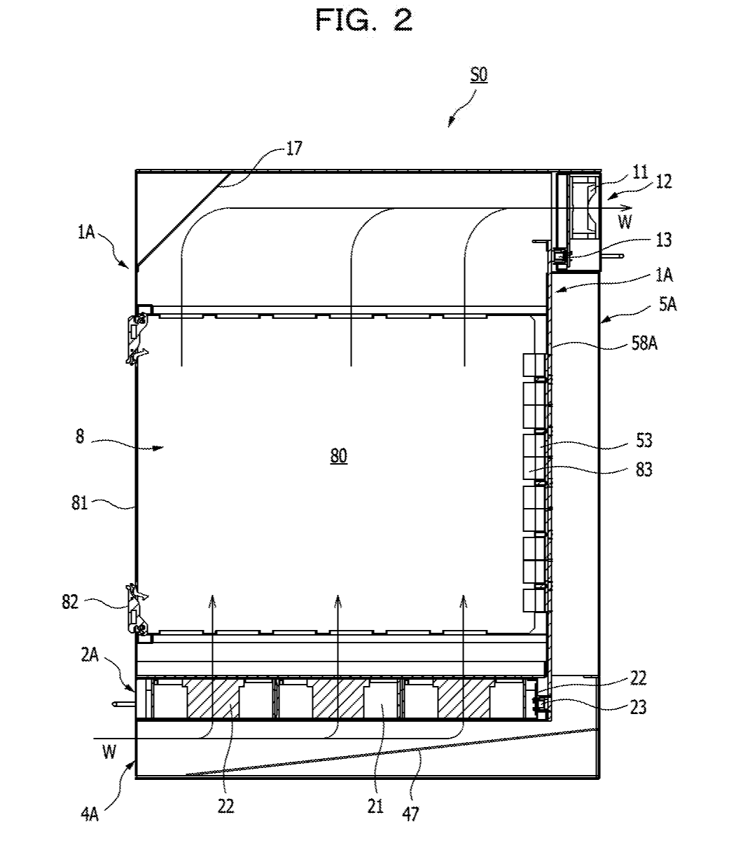

Hereinafter, using the accompanying drawings, modes of the application are described in detail based on concrete embodiments. The same constituent components as those of the shelf apparatus for plug-in units according to the comparative technique described using FIGS. 1A, 1B, and 2 are given the same reference numerals.

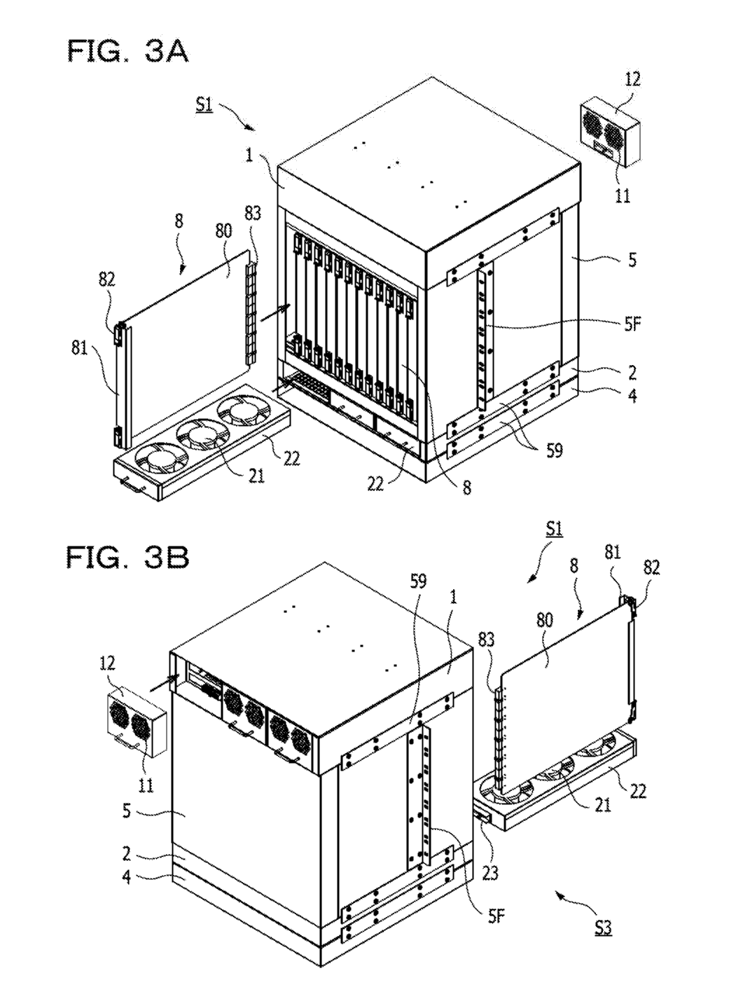

FIG. 3A is a front-right perspective view of a shelf apparatus S1 for plug-in units (hereinafter, just referred to as a shelf apparatus S1) of a first embodiment. In FIG. 3A, one of plug-in units 8, one of pull-fan units 12, and one of push-fan units 22 are detached from the shelf apparatus S1. FIG. 3B is a rear left perspective view of the shelf apparatus S1 illustrated in FIG. 3A. FIG. 3B illustrates the shelf apparatus S1 with one of the plug-in units 8, one of the pull-fan units 12, and one of the push-fan units 22 detached. The plug-in units 8, pull-fan units 12, and push-fan units 22 have the same structures as those of the comparative technique. The same constituent members are given the same reference numerals, and the description of the structures thereof is omitted. The shelf apparatus S1 is mounted in a not-illustrated rack for use by attachment flanges 5F provided on the right and left side surface of a body 5 in a similar manner to the shelf apparatus S0 of the comparative technique.

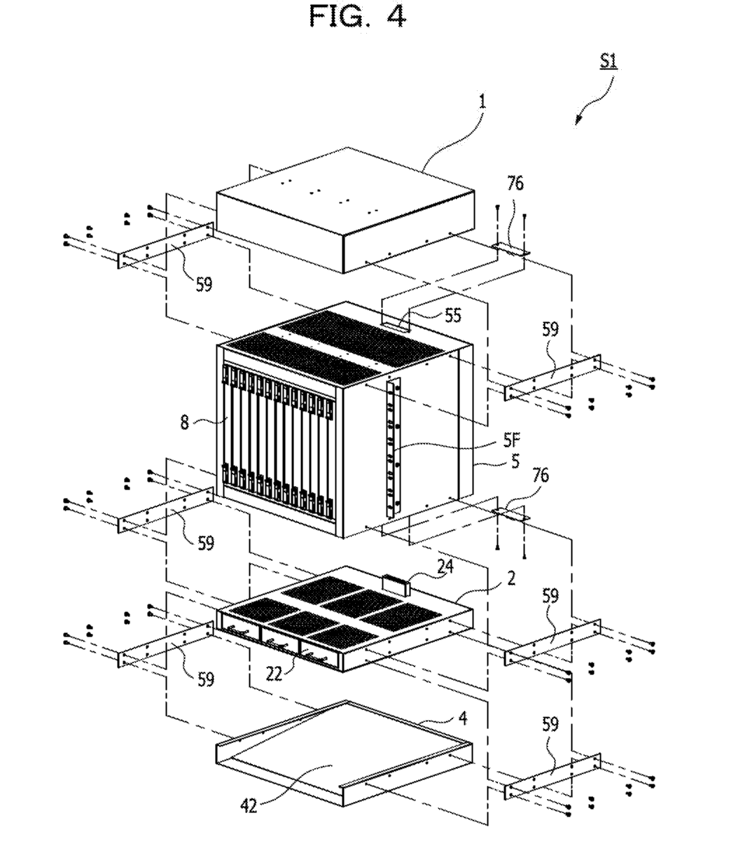

FIG. 4 is an exploded perspective view illustrating the structure of the shelf apparatus S1 illustrated in FIG. 3A. In the shelf apparatus S1, a first air-cooling device 1, a body 5, a second air-cooling device 2, and an air guide device 4, which correspond to the upper cooling device 1A, body section 5A, lower cooling device 2A, and air guide device 4A, respectively, are independent from each other. The independent first air-cooling device 1, body 5, second air-cooling device 2, and air guide device 4 are selectively combined according to the specification of the shelf apparatus S1, stacked, and coupled with joint plates 59 to be assembled. The shelf apparatus S1 is formed by stacking the air guide device 4, second air-cooling device 2, body 5, and first air-cooling device 1 in this order from the bottom and attaching the joint plates 59 to the boundaries between the above devices with screws to fix the same.

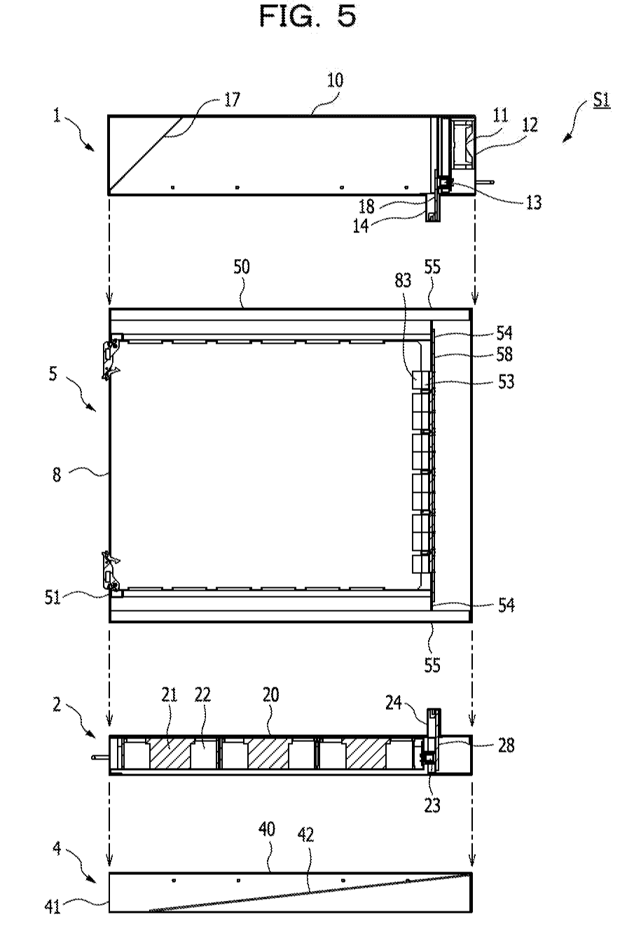

Herein, a description is individually given of the structures of the air guide device 4, second air-cooling device 2, body 5, and first air-cooling device 1, which constitute the shelf apparatus S1 using the exploded cross-sectional view illustrated in FIG. 5. The air guide device 4, which is located at the bottom of the shelf apparatus S1, includes an opening 41 at the front side of a casing 40 and takes in air serving as cooling wind through the opening 41. Within the casing 40, a baffle (heat baffle) 42 is provided. The baffle 42 is configured to direct upward the cooling wind taken in through the opening 41. The baffle 42 is composed of a flat plate in this embodiment but may be a curved plate which is concave upward.

In the second air-cooling device 2 stacked on the air guide device 4, three push-fan units 22 are accommodated within a casing 20 as illustrated in FIG. 3A. Each push-fan unit 22 accommodates three fans 21. The second air-cooling device 2 is provided with a second substrate 28 on the back side of the casing 20. The push-fan units 22 are detachably attached to the second substrate 28 through the respective attachment connectors 23. The second substrate 28 supplies driving power and control signal to the push-fan units 22. The second substrate 28 extends to above the top surface of the casing 20. On the second substrate 28, a connector 24 is formed. The connector 24 is configured to connect the second substrate 28 to the back plane 58 of the body 5 on the top surface of the casing 20. The structure of the connector 24 is described later.

The body 5 stacked on the second air-cooling device 2 includes an opening 51 on the front side and a casing 50 in which plural plug-in units 8 are mounted. On the back side of the casing 50, the back plane 58 is provided. On the back plane 58, attachment connectors 53 are mounted. The attachment connectors 53 are connectable to attachment connectors 83 provided in the plural plug-in units 8. The plural pug-in units 8 are detachably attached to the back plane 58 by connecting or separating the attachment connectors 83 and 53. At upper and lower ends of the back plane 58, terminals 54 are provided to connect the back plane 58 to backboards of other devices. The terminals 54 are described later.

At the positions in the top and bottom surfaces of the casing 50 corresponding to the respective terminals 54, through-holes 55 through which connectors of different devices are inserted are provided as illustrated in FIG. 4. In the shelf apparatus S1, cover plates 76 are attached with screws to close the through-holes 55 when the body 5 is not used, so that dust does not enter the unused body 5. The cover plates 76 are detached when the body 5 is coupled to another device.

The first air-cooling device 1 stacked on the body 5 is situated at the top of the assembled shelf apparatus. Within a casing 10, a baffle 17 is provided on the front side. The baffle 17 directs the flow of the cooling wind toward the back of the shelf apparatus S1. On the back side of the casing 10, the pull-fan units 12 are mounted. Each of the pull-fan units 12 includes the fans 11 configured to discharge the cooling wind having passed through the body 5, toward the back side of the body 5. In the shelf apparatus S1, as illustrated in FIG. 3B, three pull-fan units 12 each accommodating two fans 11 are mounted. On the back side of the casing 10, a first substrate 18 is provided. The pull-fan units 12 are coupled to the first substrate 18 through the attachment connectors 13. The first substrate 18 supplies driving power and control signal to the pull-fan units 12. The first substrate 18 extends to below the bottom surface of the casing 10. On the bottom surface of the casing 10, a connector 14 is provided. The connector 14 is configured to connect the first substrate 18 to the back plane 58 of the body 5. The structure of the connector 14 is described later.

In the shelf apparatus S1, the air guide device 4 is installed at first, and the second air-cooling device 2 is installed on the air guide device 4. On the second air-cooling device 2, the body 5 is installed. The body 5 is installed by inserting the connector 24, which is provided on the upper surface of the second air-cooling device 2, into the through-hole 55 provided in the bottom surface of the body 5. When the body 5 is installed on the second air-cooling device 2, the first substrate 18 of the second air-cooling device 2 is coupled to the back plane 58 of the body 5 through the connector 24. At last, the first air-cooling device 1 is installed on the body 5 with the connector 14 of the first air-cooling device 1 being inserted into the through-hole 55 provided in the top surface of the body 5, thus forming the shelf apparatus S1. When the first air-cooling device 1 is attached onto the body 5, the substrate 18 of the first air-cooling device 1 is coupled to the back plane 58 of the body 5 through the connector 14.

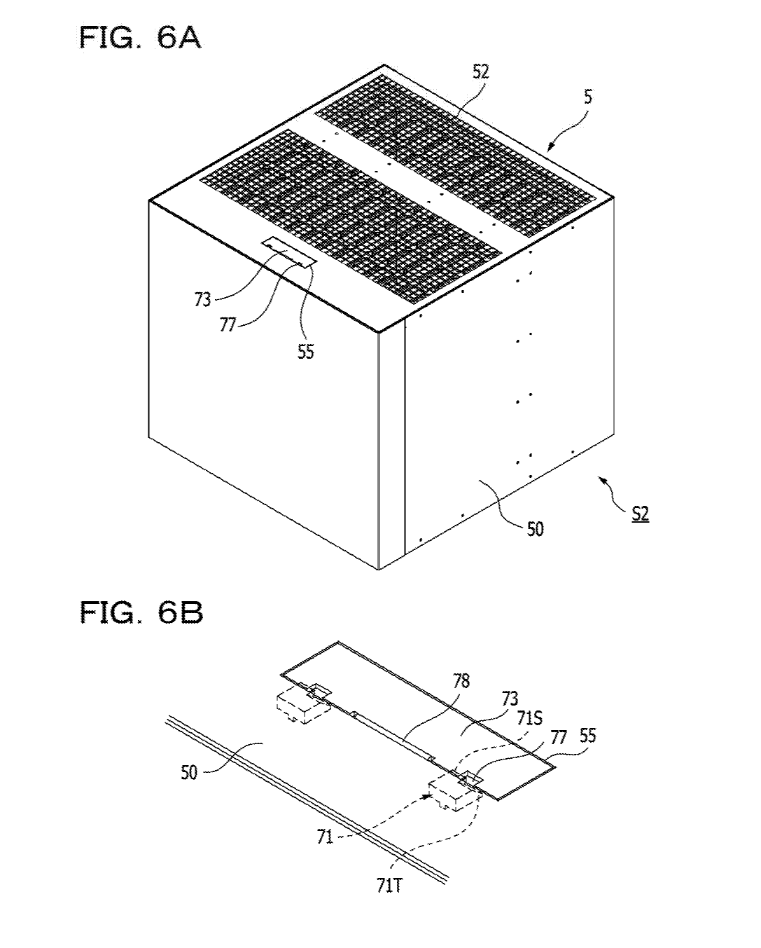

FIG. 6A is a rear-left perspective view of a body 5 of a shelf apparatus S2 for plug-in units (hereinafter, referred to as just a shelf apparatus S2) according to a second embodiment. FIG. 6B is a main part enlarged view illustrating a part around the through-hole 55 for insertion of the first connector, which is provided in the body 5 illustrated in FIG. 6A. In the shelf apparatus S1, as illustrated in FIG. 4, the through-holes 55 provided in the body 5 are closed by screwing the cover plates 76 when the body 5 is not used. On the other hand, in the shelf apparatus S2, the through-holes 55 provided in the body 5 are provided with closing plates 73 that are openable. When the body 5 is not used, the through-holed 55 are closed by the closing plates 73. The shelf apparatus S2 differs from the shelf apparatus S1 in this term. Moreover, in the shelf apparatus S1, the cover plate 76 covers the through-hole 55 from above as illustrated in FIG. 4. On the other hand, in the shelf apparatus S2, each closing plate 73 is provided within the inner circumference of the corresponding through-hole 55. The shelf apparatus S2 differs from the shelf apparatus S1 in this term. FIGS. 6A and 6B illustrate only the through-hole 55 located in the top surface of the casing 50 of the body 50. However, the through-hole 55 located in the bottom plane of the casing 50 is provided with the closing plate 73 having the same structure.

In the second embodiment, each closing plate 73, which closes the corresponding through-hole 55 provided in the casing 50 of the body 5, is opened and closed with later-described hinges. When the body 5 is not used, the closing plates 73 close the respective through-holes 55 so that the outer surface of each closing plate 73 is flush with the outer surface of the casing 50. The closing plate 73 does not open inward due to a later-described lock device even when being pressed from the outside of the casing 50. The closing plate 73 also does not open outward due to a stopper 78. The stopper 78 is provided at an edge of the closing plate 73 opposite to the hinges. FIG. 6B illustrates a slide member 71 of a first mode (hereinafter, referred to as a first slide member 71), which does not allow the closing plate 73 to open inward, the stopper 78, which does not allow the closing plate 73 to open outward, and a notch 77 to move the first slide member 71.

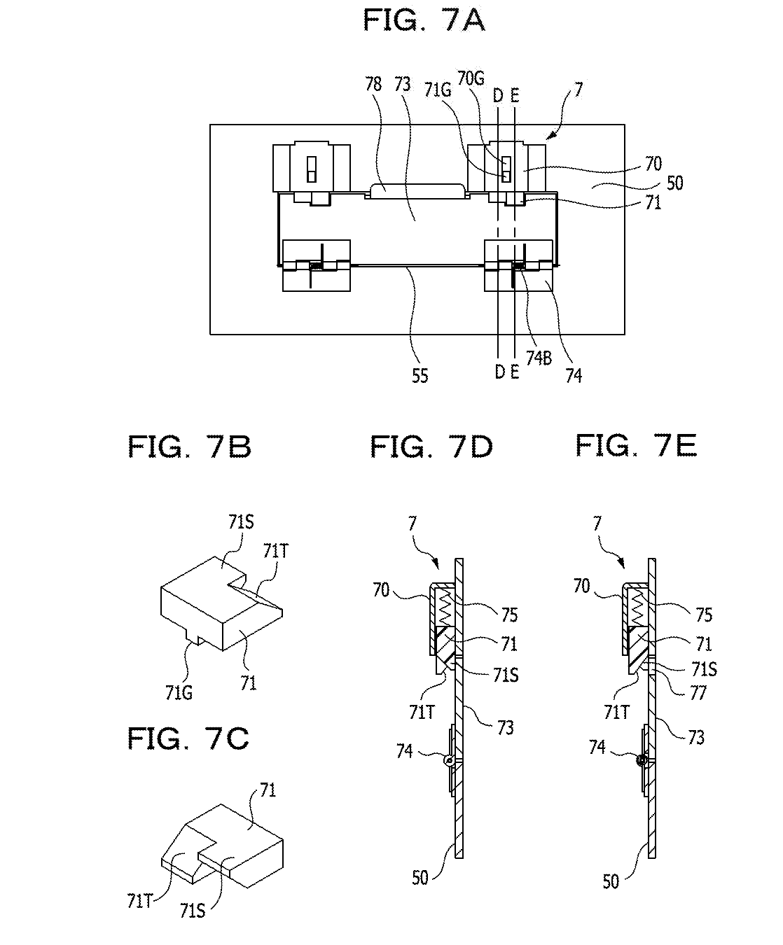

Herein, using FIGS. 7A to 7E, a description is given of the lock device 7 configured to lock the closing plate 73 closing the through-hole 55 in the shelf apparatus S2. FIG. 7A illustrates an inner view of the through-hole 55 illustrated in FIG. 6B seen from the inside of the casing 50 of the body 5. FIGS. 7B and 7C are perspective views of the first slide member 71, which is incorporated in the casing 70 of the lock device 7 which locks the closing plate 73 illustrated in FIG. 7A. FIGS. 7B and 7C are back and front perspective views of the first slide member 71, respectively. FIG. 7D is a cross-sectional view taken along a line D-D of FIG. 7A. FIG. 7E is a cross-sectional view taken along a line E-E of FIG. 7A. Herein, a description is given of only the structure of the lock device 7 of the closing plate 73 which opens and closes the through-hole 55 located on the first air-cooling device 1 side (the top surface) of the casing 50. The lock device 7 for the closing plate 73 which opens and closes the through-hole 55 located on the second air-cooling device 2 side (the bottom surface) of the casing 50 have the same structure.

As illustrated in FIG. 7A, two hinges 74 are attached between the back surface of the closing plate 73 and the back surface of the casing 50. The closing plate 73 is energized in a direction by torsional springs 74B, which are provided in the respective hinges 74, so as to close the through-hole 55. The stopper 78 is formed on the edge of the closing plate 73 opposite to the edge where the hinges 74 are attached. The closing plate 73 energized by the hinges 74 are configured to stop at the position of the through-hole 55. On the both sides of the stopper 78 on the inner surface of the casing 50, the lock devices 7, which do not allow the closing plate 73 to open inward, are attached.

The first slide member 71 as illustrated in FIGS. 7B and 7C is provided within the casing 70 of each lock device 7. The surface of the first slide member 71 on the through-hole 55 side is composed of two sections, one of which constitutes a latch section 71S. The other constitutes a slope 71T. The casing 70 of the lock device 7 includes a slit-shaped guide hole 70G. The first slide member 71 is provided with a guide protrusion 71G, which is movable within the guide hole 70G. The first slide member 71 is movably accommodated within the casing 70 with the guide protrusion 71G being inserted in the guide hole 70G. As illustrated in FIGS. 7D and 7E, the first slide member 71 is energized by a spring 75, which is provided within the casing 70, in a direction such that the latch section 71S and slope 71T protrude from the casing 70. As also illustrated in FIG. 6B, the latch section 71S protruding from the casing 70 is located below the closing plate 73. The slope 71T is located below the notch 77 provided in the closing plate 73. The closing plate 73 is latched by the latch section 71S and is not opened even when being subjected to force from the outside of the closing plate 73.

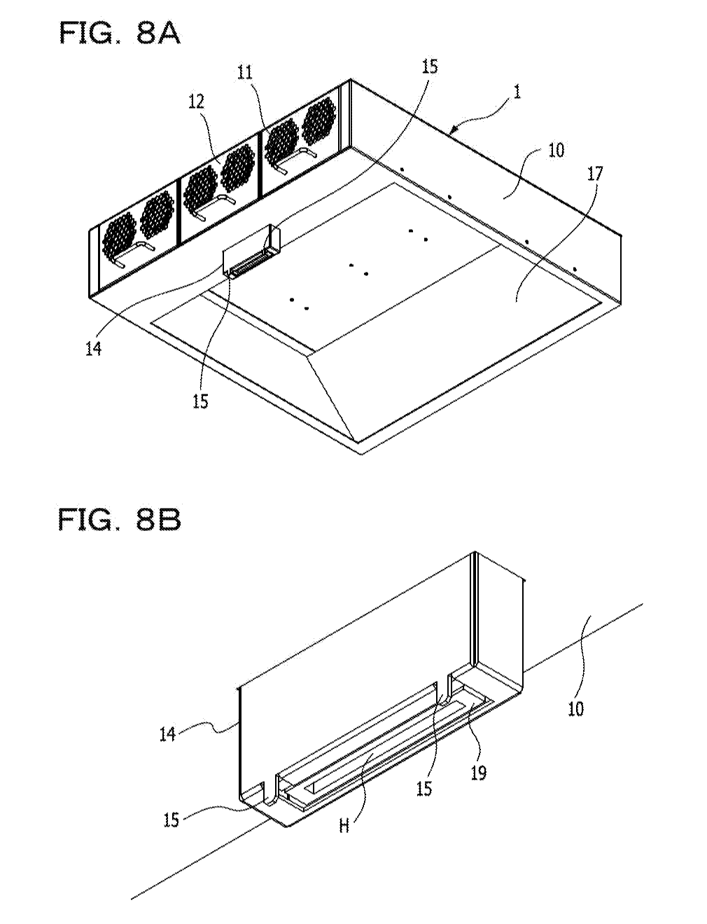

FIG. 8A is a rear-bottom perspective view of the first air-cooling device 1. FIG. 8B is a partial enlarged perspective view of the first connector 14 provided in the first air-cooling device 1 illustrated in FIG. 8A. In the first air-cooling device 1, as illustrated in FIG. 5, the end of the first collector 14 has a flat surface. In the first air-cooling device 1 of the shelf apparatus S2, the end of the first connector 14 is provided with two protruding unlocking tongues 15. The positions of the two unlocking tongues 15 correspond to the positions of the two notches 77, which are provided in the closing plate 73, when the first connector 14 is inserted into the through-hole 55 illustrated in FIG. 6B.

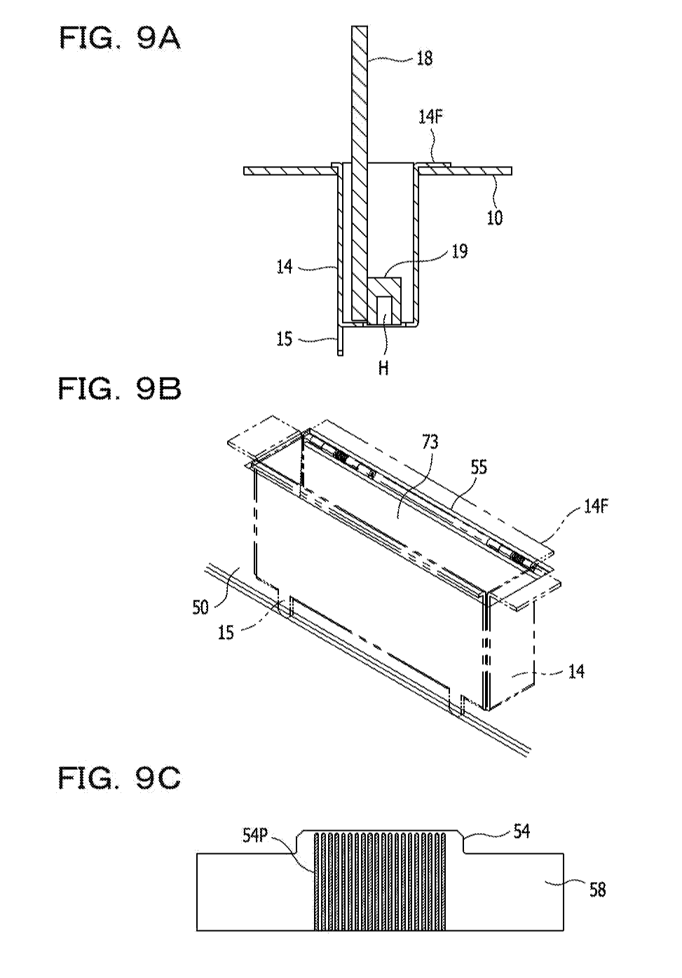

FIG. 9A is a cross-sectional view of the first connector 14 illustrated in FIG. 8B. FIG. 9B is a partial enlarged perspective view of the same part as FIG. 6B, illustrating the state where the closing plate configured to close the through-hole 55 is opened by the first connector 14. FIG. 9C is a partial view illustrating a terminal section 54 of the back plane 58 located within the through-hole 55 illustrated in FIG. 9B. In FIG. 9C, the terminal section 54 is coupled to the first connector 14. The terminal section 54 includes a circuit pattern 54P, which is coupled to a terminal connection section 19 located within the first connector 14.

As illustrated in FIG. 9A, the first substrate 18 used to attach the pull-fan units 12 is provided within the first connector 14 which is provided on the bottom surface of the casing 10 of the first air-cooling device 1 in a similar manner to the first connector 14 of the shelf apparatus S1. The terminal connection section 19 is provided at the end of the first substrate 18 which is located within the first connector 14. A terminal insertion hole H of the terminal connection section 19 is opened in the end of the first connector 14 as illustrated in FIG. 8B. The end of the first connector 14 is also provided with the unlocking tongues 15 as described above.

FIG. 9B illustrates the state where the first connector 14 illustrated in FIG. 9A is inserted in the through-hole 55. In FIG. 9B, the first connector 14 inserted into the through-hole 55 is indicated by dashed and two-dotted line for comparison of the state of the closing plate 73 with that illustrated in FIG. 6B. When the first connector 14 is inserted into the through-hole 55, the terminal section 54 of the back plane 58 illustrated in FIG. 9C is inserted into the terminal insertion hole H of the terminal connection section 19, which is provided in the first substrate 18. The first substrate 18 is then coupled to the back plane 58.

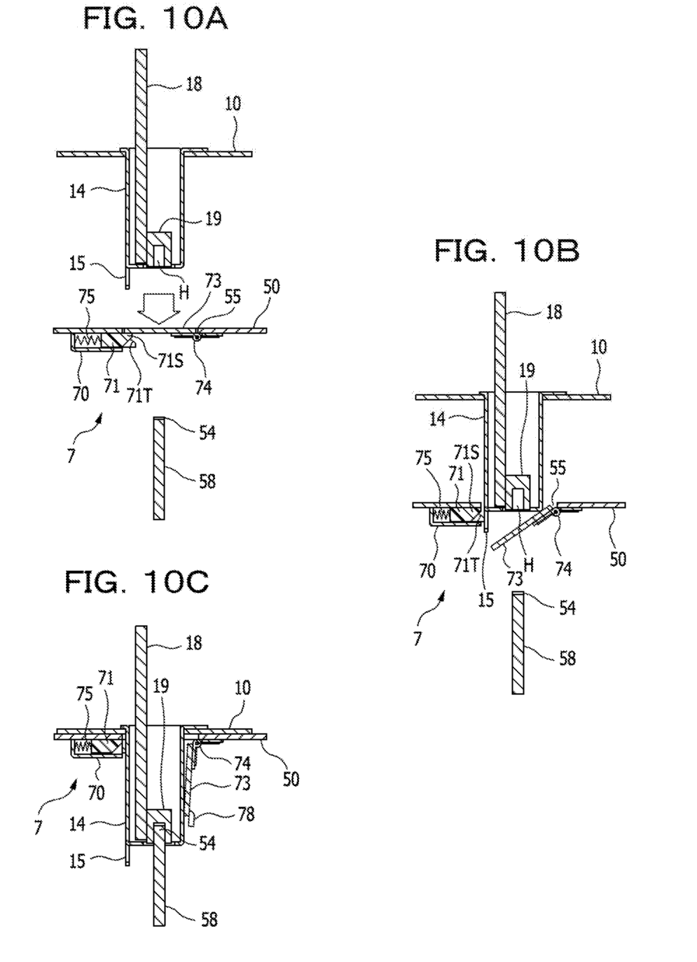

Using FIGS. 10A, 10B, and 10C, a description is given of the process in which the first connector 14 illustrated in FIG. 9A is inserted into the through-hole 55 and the terminal section 54 of the back plane 58 is inserted into the terminal insertion hole H of the terminal connection section 19. FIG. 10A is a partial enlarged cross-sectional view illustrating the state where the first connector 14 has come close to the through-hole 55 illustrated in FIG. 6B in the process of attaching the first air-cooling device 1 to the body 5.

When the first connector 14 has come closer to the through-hole 55 from the state illustrated in FIG. 10A, each unlocking tongue 15 of the first connector 14 is first inserted into the corresponding notch 77 provided in the closing plate 73 (see FIG. 6B). The unlocking tongue 15 inserted in the notch 77 comes into contact with the slope 71T of the first slide member 71 located just below the notch 77 to press the slope 71T. When the slope 71T is pressed by the unlocking tongue 15, the first slide member 71 compresses the spring 75 as sinking into the casing 70 of the lock device 7. When the first slide member 71 is sunk into the casing 70, the latch section 71S of the first slide member 71 which has latched the closing plate 73 moves out from below the closing plate 73 and does not latch the closing plate 73. This allows the closing plate 73 to move toward the inside of the casing 50 of the body 5.

When the end of the first connector 14 then comes into contact with the closing plate 73, as illustrated in FIG. 10B, the closing plate 73 is opened along with movement of the first connector 14 being inserted into the through-hole 55. As illustrated in FIG. 10C, the terminal section 54 of the back plane 58, which is incorporated within the body 5, is coupled to the terminal connection section 19 mounted on the first substrate 18. The first substrate 18 is thus coupled to the back plane 58. The same operation as described above is performed in the process of attaching the second air-cooling device 2 to the bottom of the body 5. A second connector 24 provided in the top surface of the casing 20 of the second air-cooling device 2 is inserted into the through-hole 55 which is provided in the bottom surface of the casing 50 of the body 5. The operation of the lock devices 7 to attach the second air-cooling device 2 to the bottom of the body 5 is therefore not described.

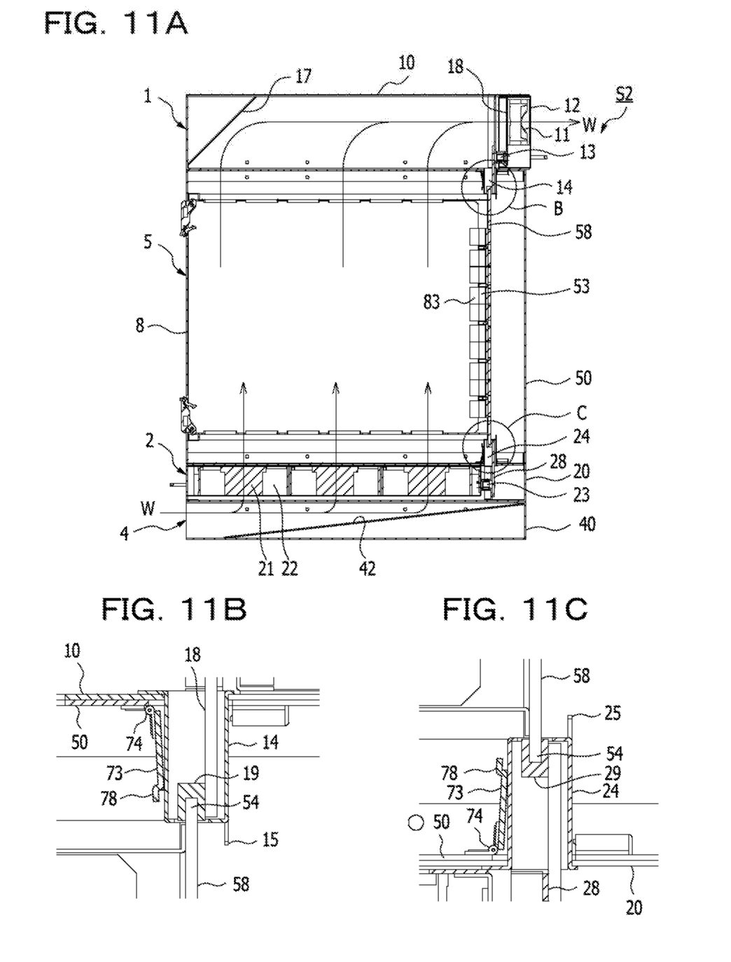

FIG. 11A illustrates a vertical sectional view of the shelf apparatus S2. In FIG. 11A, the first air-cooling device 1 is attached to the top of the body 5, and the second air-cooling device 2 is attached to the bottom of the body 5. Moreover, the air guide device 4 is attached to the bottom of the second air-cooling device 2. FIG. 11B is a partial enlarged sectional view of a part B of FIG. 11A. FIG. 11C is a partial enlarged sectional view of a part C of FIG. 11A. In the shelf apparatus S2 illustrated in FIG. 11A, the front side of the shelf apparatus S2 is located to the left while the back side of the shelf apparatus S2 is located to the right. When the first air-cooling device 1 is attached to the body 5, the back plane 58 incorporated in the body 5 is coupled to the first substrate 18 through the terminal connection section 19 as illustrated in FIG. 11B. As illustrated in FIG. 11C, when the second air-cooling device 2 is attached to the body 5, the back plane 58 incorporated in the body 5 is coupled to the second substrate 28 through the terminal connection section 29.

In the shelf apparatus S2 configured as illustrated in FIG. 11A, similarly, the air guide device 4 located at the bottom is opened on the front side of the body 5 and includes the baffle 42, which directs upward the flow of the cooling wind taken inside. In the second air-cooling device 2 situated on the air guide device 4, push-fan units 22 are mounted. Each of the push-fan units 22 includes three fans 21, which send the cooling wind toward the plug-in units 8. The push-fan units 22 are attached to the second substrate 28 through the attachment connectors 23. The cooling wind W taken into the body 5 from the air guide device 4 changes the direction due to the baffle 42 to be sent to the second air-cooling device 2. In the second air-cooling device 2, the push-fan units 22 send the cooling wind W toward the plug-in units 8, so that the plug-in units 8 are cooled by the cooling wind W.

Within the back side of the body 5, the back plane 58 is provided. The lower part of the back plane 58 is coupled to the second substrate 28 through the terminal connection section 29 and supplies power to the push-fan units 22 through the second substrate 28. The back plane 58 is used for failure detection of fan motors or other purposes. In the center of the back plane 58, plural attachment connectors 53 are provided. The attachment connectors 53 are coupled to the respective attachment connectors 83 of the plug-in units 8. Upper part of the back plane 58 is coupled to the first substrate 18 through the terminal connection section 19 to supply power to the pull-fan units 12 through the first substrate 18. The cooling wind W having cooled the plug-in units 8 changes the direction due to the baffle 17 of the first air-cooling device 1 and is then discharged out of the body 5 by the pull-fan units 12.

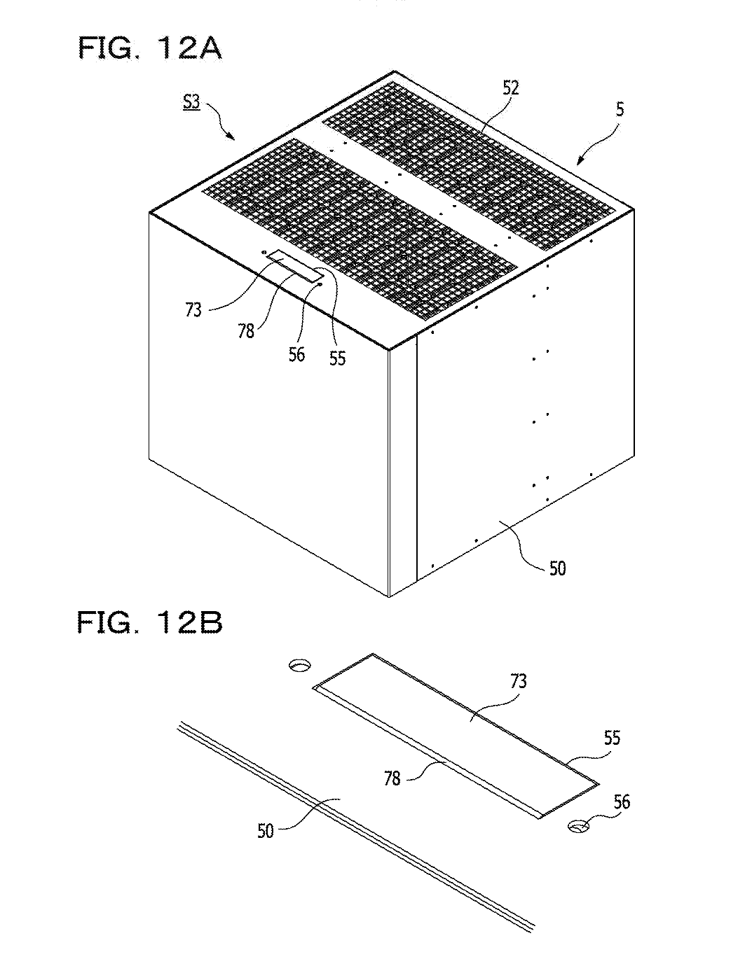

FIG. 12A is a rear perspective view of a body 5 of a shelf apparatus S3 for plug-in units (hereinafter, referred to as a shelf apparatus S3) according to a third embodiment. FIG. 12B is a main part enlarged view illustrating a part around a through-hole 55 for insertion of a first connector provided in the body 5 illustrated in FIG. 12A. In the shelf apparatus S1, as illustrated in FIG. 4, the through-holes 55 provided in the body 5 are closed by screwing the cover plates 76 when the body 5 is not used. In the shelf apparatus S3, the through-holes 55 provided in the body 5 are provided with openable closing plates 73. The through-holes 55 are closed with the closing plates 73 when the body 5 is not used. The shelf apparatus S3 differs from the shelf apparatus S1 in this term. FIGS. 12A and 12B illustrate only the through-hole 55 located in the top surface of the casing 50 of the body 5. However, another closing plate 73 having the same structure is also attached to the through-hole 55 located in the bottom surface of the casing 50.

In the third embodiment, the closing plates 73, which are provided in the casing 50 of the body 5 and close the respective through-holes 55, are opened and closed with hinges. When the body 5 is not used, each closing plate 73 closes the corresponding through-hole 55 so that the outer surface of the closing plate 73 is flush with the outer surface of the casing 50. The closing plate 73 does not open inward due to a later-described lock device even when being pressed from the outside of the casing 50. The closing plate 73 also does not open outward due to the stopper 78, which is provided in an edge of the closing plate 73 opposite to the hinges. FIG. 12B illustrates the stopper 78, which is configured not to allow the closing plate 73 to open outward and the guide holes 56 into which later-described guide pins configured to move the slide members are inserted. The slide members configured not to allow the closing plate 73 to open inward are not illustrated.

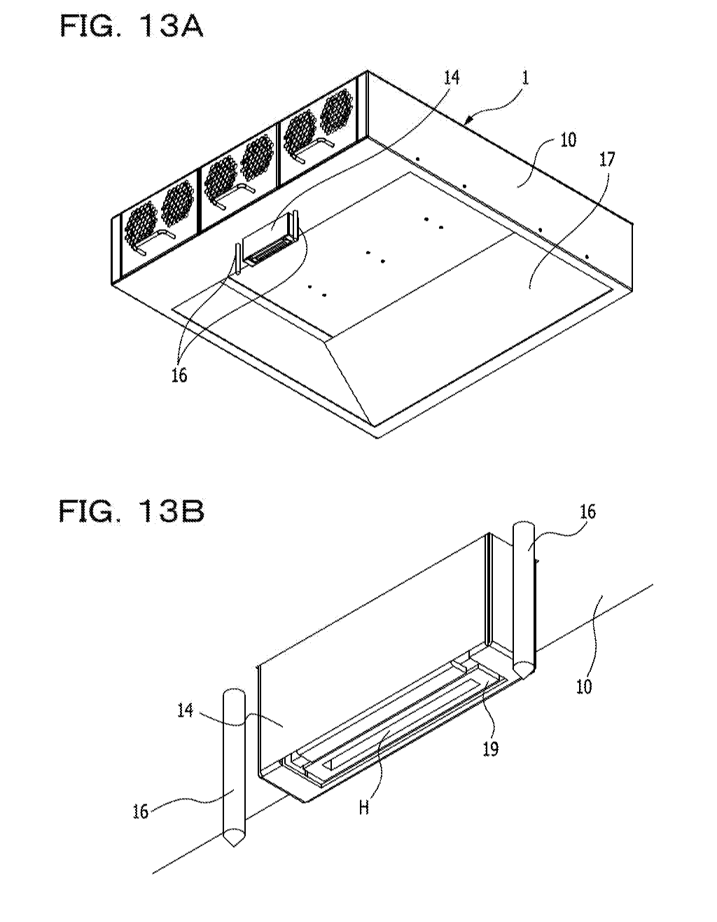

FIG. 13A is a rear-bottom perspective view of the first air-cooling device 1. FIG. 13B is a partial enlarged perspective view of a part around the first connector 14 of the first air-cooling device 1 illustrated in FIG. 13A. Similarly to the end of the first air-cooling device 1 illustrated in FIG. 5, the end of the first collector 14 has a flat surface. In the first air-cooling device 1 illustrated in FIG. 13A, two guide pins 16 protrude on the casing 10 of the first air-cooling device 1, on both sides of the first connector 14. Each guide pin 16 has a tapered tip. The positions of the two guide pins 16 correspond to the positions of the two guide holes 56, which are provided in the casing 50 of the body 5 and on both sides of the closing plate 73, in the process of inserting the first connector 14 into the through-hole 55 illustrated in FIG. 12B.

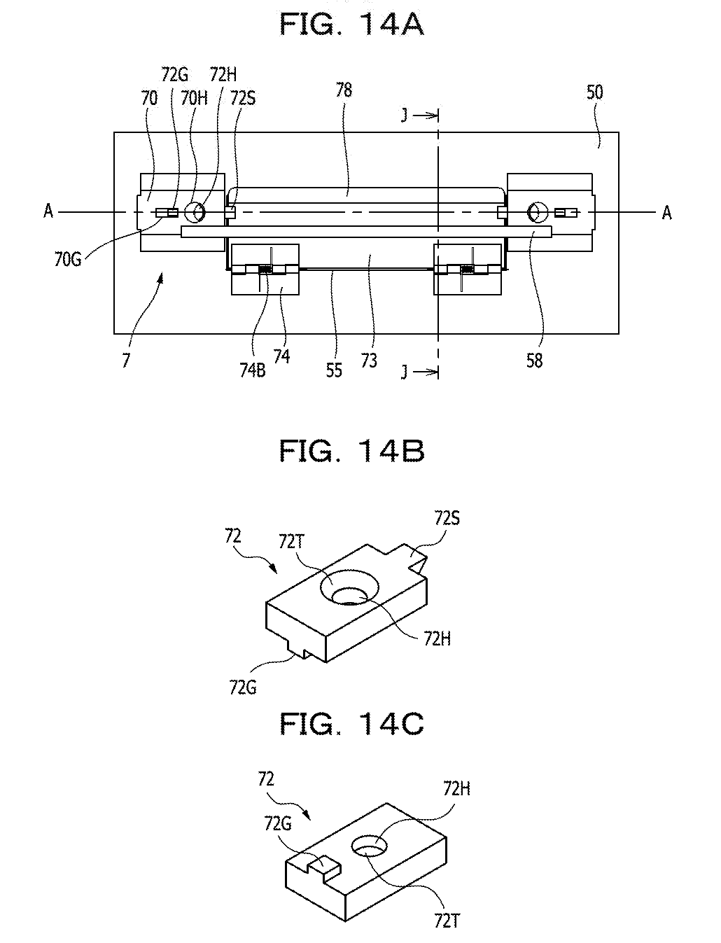

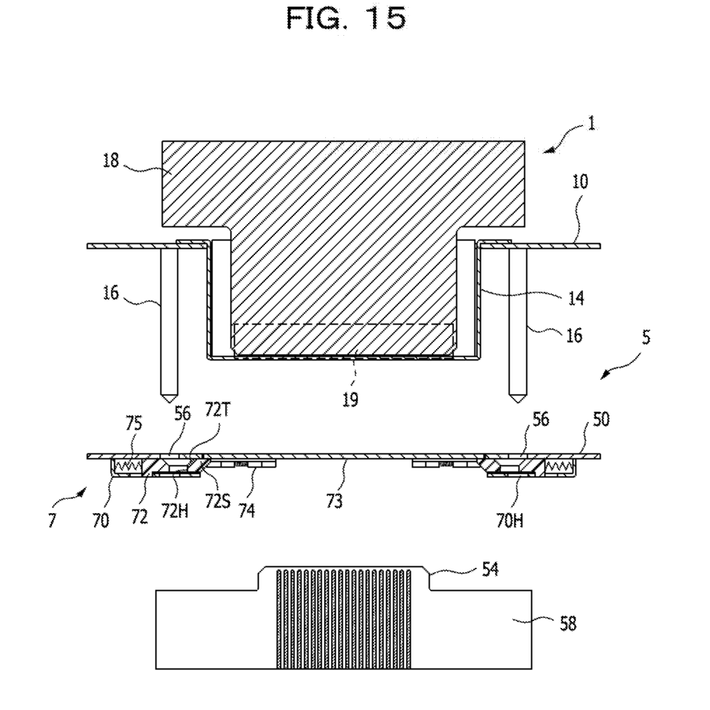

Herein, using FIGS. 14A to 14C and FIG. 15, a description is given of lock devices 7, each of which is configured to open and close the corresponding closing plate 73 and lock the closing plate 73 at the position where the closing plate 73 closes the through-hole 55. FIG. 14A is an inner view of a part around the through-hole 55 illustrated in FIG. 12B, as seen from the inside of the casing 50 of the body 5. FIGS. 14B and 14C illustrate a slide member 72 of a second mode (hereinafter, referred to as a second slide member 72) which is incorporated in the casing 70 of each lock device 7 (illustrated in FIG. 14A) configured to lock the closing plate 73. FIGS. 14B and 14C are top and bottom perspective views of the second slide member 72, respectively. FIG. 15 illustrates a cross-sectional view taken along a line A-A in FIG. 14A. Herein, a description is given of the structure of the lock device 7 including the closing plate 73 closing the through-hole 55 located on the first air-cooling device 1 side of the casing 50. However, the lock device 7 including the closing plate 73 which opens and closes the through-hole 55 located on the second air-cooling device 2 side of the casing 50 has the same structure.

As illustrated in FIG. 14A, the two hinges 74 are attached across the back surface of the closing plate 73 and the back surface of the casing 50. The closing plate 73 is energized by torsional springs 74B provided in the respective hinges 74 in a direction so as to close the through-hole 55. A stopper 78 is formed on an edge of the closing plate 73 opposite to the edge where the hinges 74 are attached. The closing plate 73 energized by the hinges 74 are configured to stop at the position of the through-hole 55. On both sides of the stopper 78 in the inner surface of the casing 50, the lock devices 7, which do not allow the closing plate 73 to open inward, are attached.

Within the casing 70 of each lock device 7, the second slide member 72 illustrated in FIGS. 14B and 14C is provided. The surface of the second slide member 72 on the through-hole 55 side partially protrudes to form a latch section 72S. The opposite surface thereto is flat. The casing 70 of the lock device 7 includes a slit-shaped guide hole 70G. The second slide member 72 is provided with a guide protrusion 72G, which is movable within the guide hole 70G. The second slide member 72 is movably accommodated within the casing 70 with the guide protrusion 72G being inserted in the guide hole 70G. As illustrated in FIG. 15, the second slide member 72 is energized by a spring 75, which is provided within the casing 70 such that the latch section 72S protrudes from the casing 70. The latch section 72S protruding from the casing 70 is located below the closing plate 73. The closing plate 73 is therefore latched by the latch section 72S and is not opened even when being pressed from the outside of the closing plate 73.

In the upper surface of the second slide member 72, a tapered hole 72T is provided. The tapered hole 72T does not reach the lower surface. The tapered hole 72T is coupled to a communication hole 72H which is opened in the lower surface of the second slide member 72. The tapered hole 72T and communication hole 72H are formed coaxially. The communication hole 72H has a diameter equal to that of the guide hole 56 in the casing 50 of the body 5. The diameter of the communication hole 72H is large enough for the guide pin 16 to be inserted therethrough. On the other hand, the casing 70, which accommodates the second slide member 72, is provided with a hole 70H at a position facing the guide hole 56, which is provided in the casing 50 of the body 5. The hole 70H has a size equal to the guide hole 56 and is large enough for the guide pin 16 to be inserted therethrough.

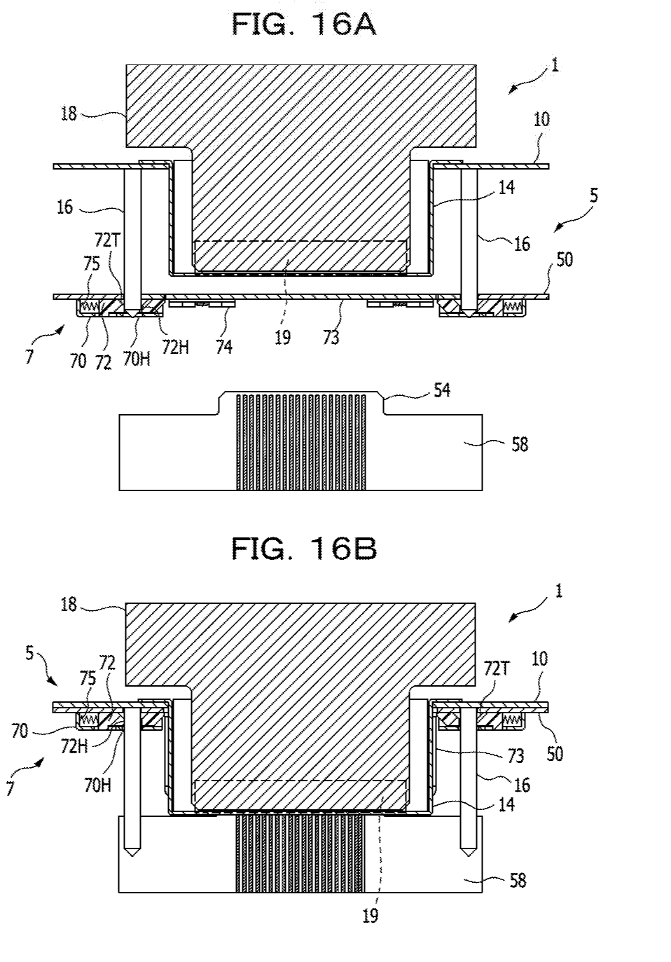

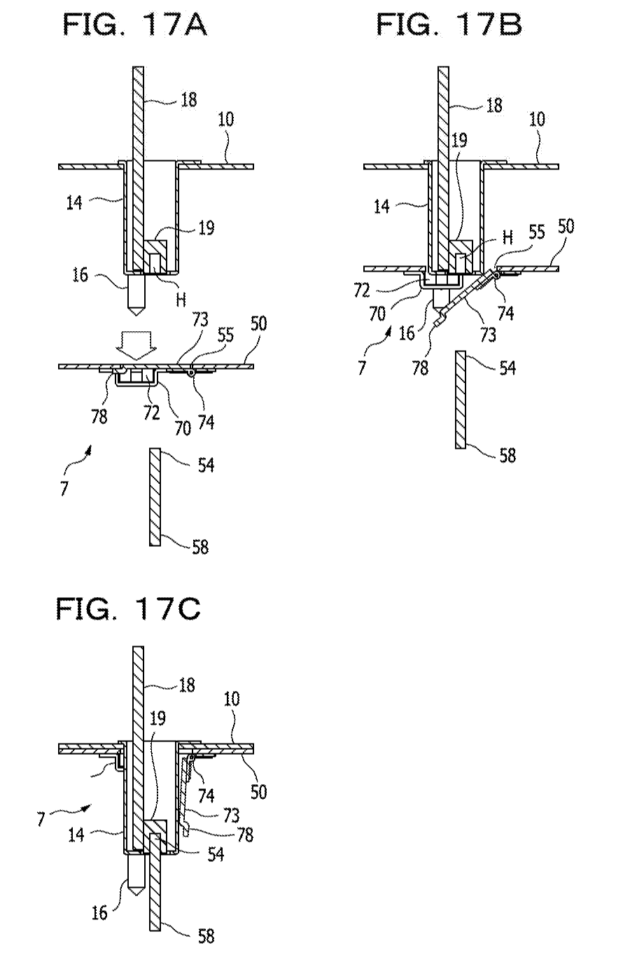

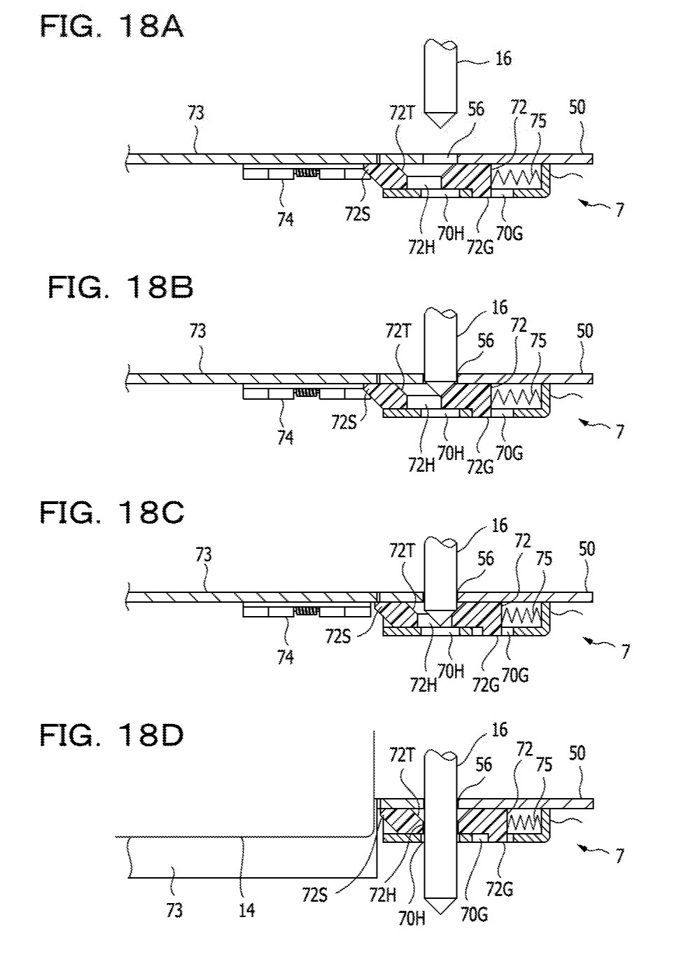

Herein, using FIGS. 15 to 18D, a description is given of the process in which the first connector 14 illustrated in FIG. 15 is inserted into the through-hole 55 so that the terminal section 54 of the back plane 58 is inserted into the terminal connection section 19. FIGS. 16A and 16B illustrate cross sections of the first air-cooling device 1 and the casing 50 of the body 50 in the same direction as those illustrated in FIG. 15. FIGS. 17A to 17C illustrate cross-sections in the orthogonal direction to that in FIG. 15. FIGS. 18A to 18D are partial enlarged cross-sectional views illustrating the slide operation of the second slide member 72 by the guide pins 16 in more detail. FIGS. 18A to 18D illustrate the slide operation of the slide member incorporated within one of the lock mechanisms for the closing plate incorporated in the body 5, which is performed by the guide pin 16 provided on each side of the first connector 14 in the third embodiment in the process of attaching the first air-cooling device 1 to the body 5.

FIGS. 15, 17A, and 18A illustrate the state where the first connector 14 has come close to the through-hole 55 in the process of attaching the first air-cooling device 1 to the body 5. In this state, the tip of the guide pin 16 of the first connector 14 faces the guide hole 56 provided in the casing 50 of the body 5, and the axis of the guide pin 16 agrees with the center of the guide hole 56. The closing plate 73 closing the through-hole 55 is locked by the lock devices 7 and the stopper 78, which is provided in the closing plate 73, and is fixed at the position illustrated in FIGS. 15, 17A, and 18A.

As the first connector 14 further approaches the through-hole 55 from the state illustrated in FIGS. 15, 17A, and 18A, the tapered tip of the guide pin 16 passes through the guide hole 56 and comes into contact with the slope of the tapered hole 72T of the second slide member 72 which is located just below the guide hole 56. This state is illustrated in FIG. 18B. As the first connector 14 further approaches the through-hole 55, the tapered tip of the guide pin 16 presses the slope of the tapered hole 72T, and the second slide member 72 compresses the spring 75 as moving within the casing 70 of the lock device 7. This state is illustrated in FIG. 18C.

When the second slide member 72 moves within the casing 70 by a predetermined distance, the axis of the communication hole 72H communicating with the tapered hole 72T agrees with the axis of the corresponding guide pin 16. In this state, the latch section 72S of the second slide member 72 which has latched the closing plate 73 moves from below the closing plate 73 and does not latch the closing plate 73. This allows the closing plate 73 to move toward the inside of the casing 50 of the body 5. The guide pin 16 then moves within the communication hole 72H. This state is illustrated in FIG. 16A.

When the end of the first connector 14 then comes into contact with the closing plate 73, the closing plate 73 opens along with the insertion of the first connector 14 into the through-hole 55 as illustrated in FIGS. 17B and 18D. As the first connector 14 is inserted into the through-hole 55, as illustrated in FIGS. 16B and 17C, the terminal section 54 of the back plane 58 incorporated in the body 5 is coupled to the terminal connection section 19 mounted on the first substrate 18. The first substrate 18 is thus coupled to the back plane 58. The same operation as described above is performed in the process of attaching the second air-cooling device 2 to the bottom of the body 5. A second connector 24 provided in the top surface of the casing 20 of the second air-cooling device 2 is inserted into the through-hole 55 which is provided in the bottom surface of the casing 50 of the body 5. The operation to attach the second air-cooling device 2 to the bottom of the body 5 is therefore not described.

The structure of the shelf apparatus S3 in which the first and second air-cooling devices 1 and 2 and the air guide device 4 are assembled to the body 5 is the same as the structure of the shelf apparatus S2 excepting the structures of the first and second connectors 14 and 24. The structures which couple the back plane 58 incorporated in the body 5 to the first substrate 18 through the terminal connection section 19 and couple the back plane 58 to the second substrate 28 through the terminal connection section 29 are the same as those in the shelf apparatus S2. The illustration thereof is omitted. The flow of cooling wind and the structure to supply power to the pull-fan units 12 and push-fan units 22 in the shelf apparatus S3 are the same as those in the shelf apparatus S2.

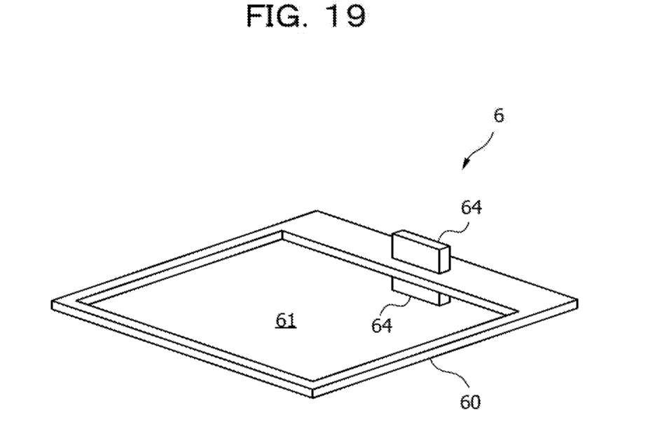

FIG. 19 is a perspective view illustrating the structure of an example of a joint device 6 used to combine the body 5 with another body 5 in a shelf apparatus. The joint device 6 includes a frame 60 and joint connectors 64. The frame 60 is provided with a ventilation hole 61 in the middle. The joint connectors 64 protrude on the respective surfaces on one side of the frame 60. The side of the frame 60 where the joint connectors 64 are provided is the side located on the back side of the shelf apparatus and is wider than the other sides. The joint connector 64 provided on the upper surface of the frame 60 includes the same structure as that of the second connector 24 of the second air-cooling device 2. The joint connector 64 provided on the lower surface of the frame 60 includes the same structure as that of the first connector 14 of the first air-cooling device 1. The terminals of the two connectors 64 are coupled to each other inside. The ventilation hole 61 allows the cooling wind to pass through between the bodies 5, which are located one above the other, without resistance. The ventilation hole 61 has a size equal to that of the ventilation holes 52 (see FIGS. 6A and 12A) provided in the top and bottom surfaces of the body 5. The joint device 6 may be composed of only the two joint connectors 64 coupled to each other without the frame 60.

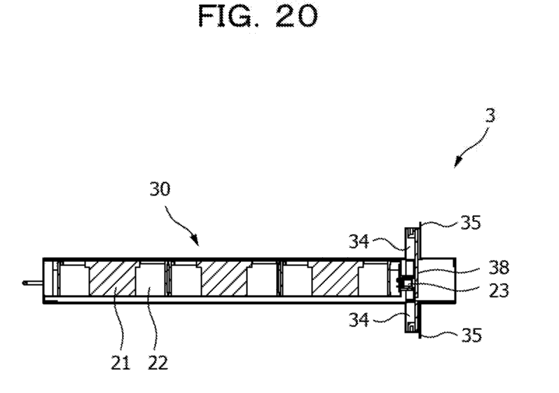

FIG. 20 is a cross-sectional view illustrating a structure of a third air-cooling device 3 as a joint device capable of combining the bodies 5 and further generating cooling wind in a shelf apparatus. The third air-cooling apparatus 3 has the same structure as that of the second air-cooling device 2 excepting the structure of third connectors 34. The third air-cooling device 3 accommodates three push-fan units 22 within a casing 30. Each of the push-fan units 22 includes three fans 21. On the back side of the casing 30, a third substrate 38 is provided. The push-fan units 22 are detachably attached to the third substrate 38 through the attachment connectors 23. The third substrate 38 supplies driving power and control signal to the push-fan units 22.

The third substrate 38 is extended to above the top surface of the casing 30 and is extended to below the bottom surface. At the extensions of the third substrate 38, the connectors 34 are provided. The extension of the third substrate 38 above the top surface of the casing 30 has the same structure as the second connector 24 provided in the second air-cooling device 2. The extension of the third substrate 38 below the bottom surface of the casing 30 has the same structure as the second connector 14 provided in the first air-cooling device 1. The third connectors 34 protruding on the top and bottom surfaces of the third air-cooling device 3 are coupled through the third substrate 38 of the third air-cooling device 3. When the two bodies 5 are stacked with the third air-cooling device 3 sandwiched therebetween, the back planes 58 of the upper and lower bodies 5 are coupled to each other.

The third air-cooling device 3, joint device 6, and an additional body 5 having the above-described structures are prepared in addition to the first air-cooling device 1, air guide device 4, and the body 5. By selectively combining the aforementioned devices, shelf apparatuses different in request specifications are implemented. A description is given of the method of manufacturing shelf apparatuses having different specifications by selectively combining the above described devices.

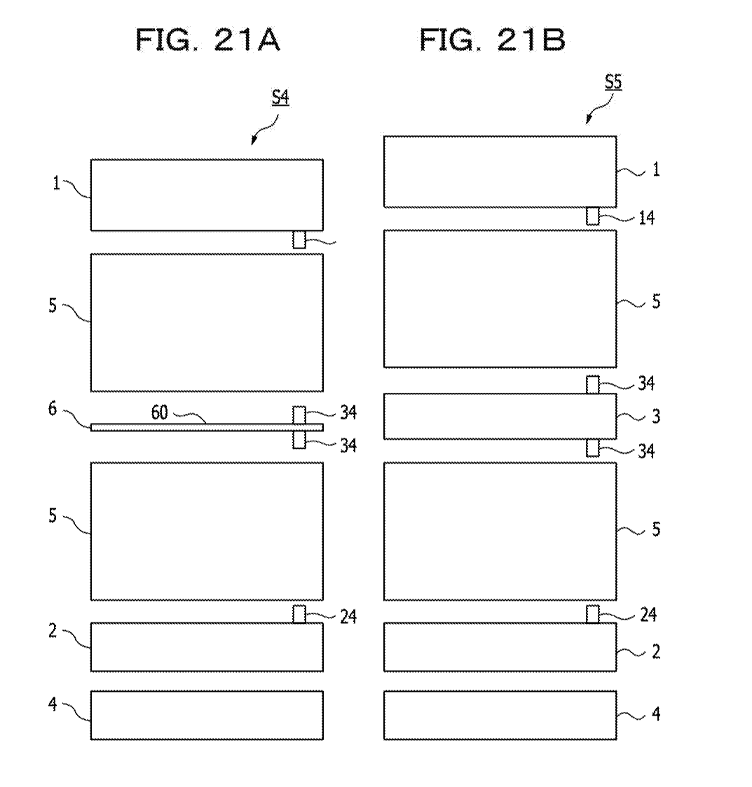

FIG. 21A is an exploded side view illustrating a shelf apparatus S4 of a fourth embodiment (hereinafter, just referred to as a shelf apparatus S4). The shelf apparatus S4 includes the air guide device 4, second air-cooling device 2, body 5, joint device 6, body 5, and first air-cooling device 1 stacked in this order. The shelf apparatus S4 is composed of two bodies 5 and one each of the other devices. The two bodies 5 located one above the other are combined by the joint device 6. The shelf apparatus S4 has a configuration obtained by adding a body 5 to any one of the first to third shelf apparatuses S1 to S3 and combining the bodies 5 through the joint device 6.

FIG. 21B is an exploded side view illustrating a shelf apparatus S5 of a fifth embodiment (hereinafter, just referred to as a shelf apparatus S5). The shelf apparatus S5 includes the air guide device 4, second air-cooling device 2, body 5, third air-cooling device 3, body 5, and first air-cooling device 1 stacked in this order. The shelf apparatus S5 is composed of two bodies 5 and one each of the other devices. The two bodies 5 located one above the other are combined by the third air-cooling device 3. The shelf apparatus S5 has a configuration obtained by adding a body 5 to any one of the first to third shelf apparatuses S1 to S3 and combining the bodies 5 by the third air-cooling device 3. The shelf apparatus S5 ensures the cooling performance even when the bodies 5 generating a large amount of heat are arranged one above the other.

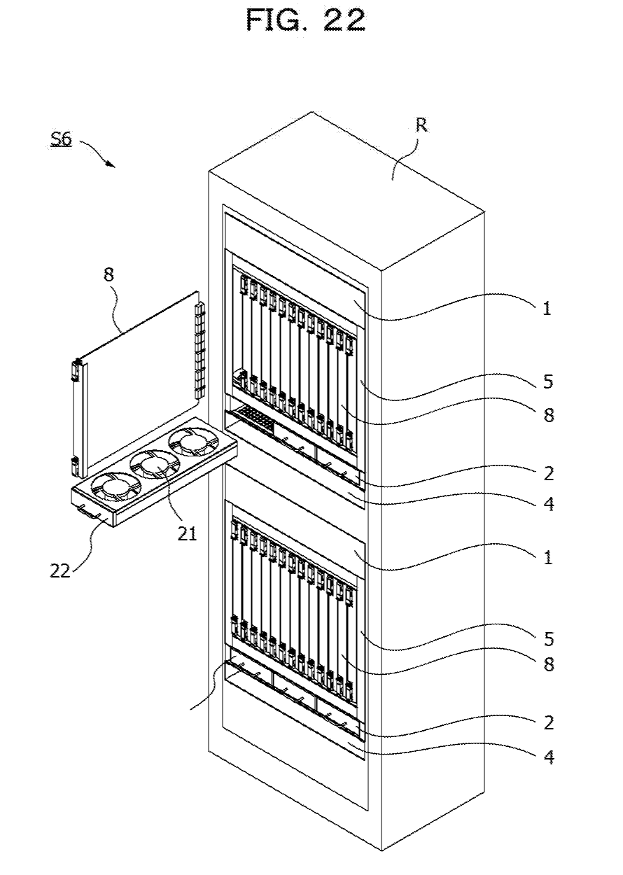

FIG. 22 is a front perspective view illustrating a shelf apparatus S6 of a sixth embodiment (hereinafter, just referred to as a shelf apparatus S6). The shelf apparatus S6 includes two each of the shelf apparatuses S1 to S3 of the first to third embodiments illustrated in FIGS. 3A to 18D which are mounted on a rack R. Each of the shelf apparatuses S1 to S3 includes the air guide device 4, second air-cooling device 2, body 5, and first air-cooling device 1 stacked in this order. The arrangement of the two bodies 5 of the shelf apparatus S6 is implemented by devising the form of the rack R without using the third-air cooling device 3 or the joint device 6 having the joint function.

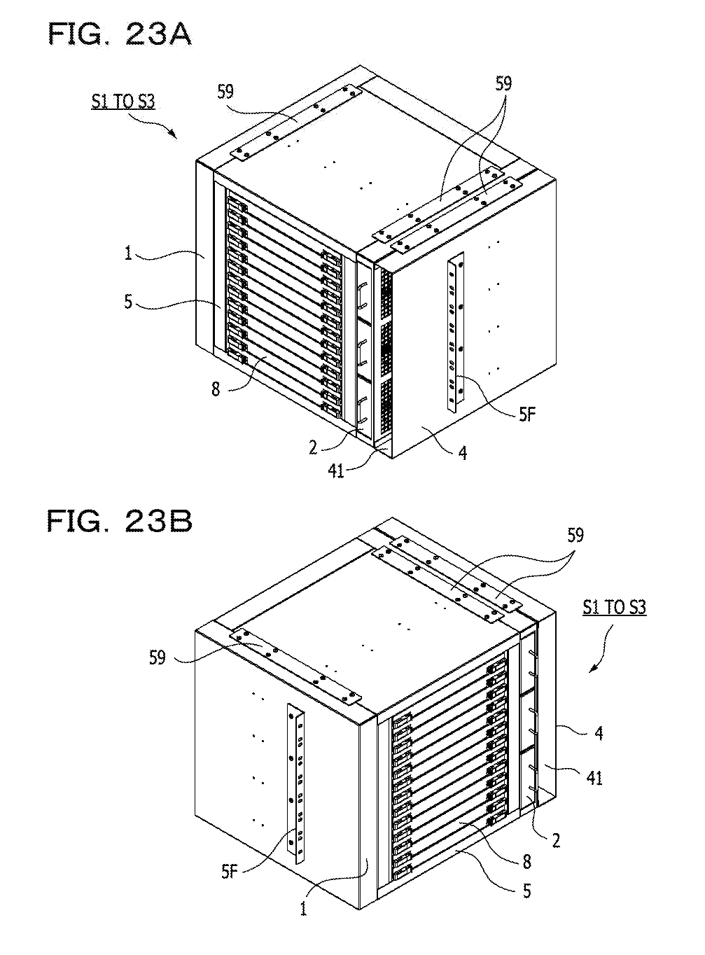

FIG. 23A illustrates a usage example in which any one of the 23 inches-wide shelf apparatuses S1 to S3 of the first to third embodiments including the body 5 is arranged transversely. FIG. 23A is a front-right perspective view of any one of the shelf apparatuses S1 to S3. FIG. 23B is a front-left perspective view of one of the shelf apparatuses S1 to S3 illustrated in FIG. 23A. The 23 inches-wide shelf apparatuses S1 to S3 of the first to third embodiments are desirably capable of taking in cooling air from the front side of the shelf apparatus and discharge the cooling air to the back side of the shelf apparatus. Each of the shelf apparatuses S1 to S3 includes one pair of the air guide device 4 and the second air-cooling device 2 and one first air-cooling device 1. In this structure, the cooling wind taken in through the opening 41 of the air guide device 4 is sent to the plug-in units 8 by the second air-cooling device 2. After cooling the plug-in units 8, the cooling wind is discharged by the first air-cooling device 1 to the back side of the shelf apparatuses S1 to S3.

In FIGS. 23A and 23B, the pair of the air guide device 4 and the second air-cooling apparatus 2 is provided to the right side of the body 5, and the first air-cooling device 1 is provided to the left side. However, the air guide device 4 may be provided instead of the first air-cooling device 1. In this case, the air guide device 4 is attached to the left side of the body 5 so that the opening 41 of the air guide device 4 is located on the back side of the shelf apparatuses S1 to S3. In this structure, the cooling wind taken in through the opening 41 of the air guide device 4 adjacent to the second air-cooling device 2 is sent to the plug-in units 8 by the second air-cooling device 2. After cooling the plug-in units 8, the cooling wind is discharged to the back through the opening 41 of the air guide device 4 attached to the left side of the body 5.

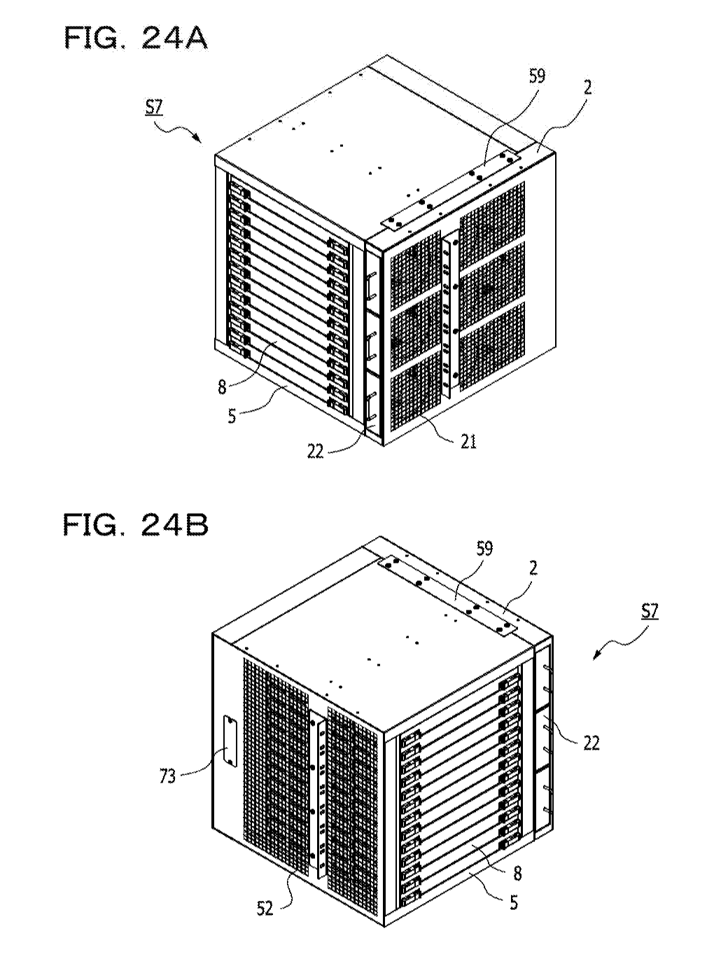

FIG. 24A is a front-right perspective view of a 19 inches-wide shelf apparatus S7 of a seventh embodiment (hereinafter, just referred to as a shelf apparatus S7) including one body 5. FIG. 24B is a front-left perspective view of the shelf apparatus S7 illustrated in FIG. 24A. In the shelf apparatus S7, the second air-cooling device 2 is attached to the body 5. The second air-cooling device 2 and body 5 are transversely situated for use. Some 23 inches-wide shelf apparatuses are desirably capable of operating so that the cooling air is taken in from the front side of the shelf apparatus and is discharged to the back side of the shelf apparatus as described above (for example, shelf apparatuses for North American stations). The 19 inches-wide shelf apparatus has flexibility in designing the directions that cooling air is taken in from and is discharged to. In the seventh shelf apparatus S7, therefore, only the second air-cooling device 2 is attached to the right side of the body 5 (in the front view) to flow the cooling wind transversely to cool the shelf apparatus S7.

To apply the shelf apparatus S7 illustrated in FIGS. 24A and 24B to apparatuses for North American stations, the flow path of cooling wind has to be changed so that the cooling wind is taken in from the front and is discharged to the back and to change the apparatus width. In this case, according to the application, the shelf apparatus S7 may be converted to the shelf apparatus S6 illustrated in FIGS. 23A and 23B by adding the air guide device 4 and first air-cooling device 1 to the shelf apparatus S7. In this case, the joint portions of each device of 19 inches-wide shelf apparatuses request to have the same dimensions to those of each device of 23 inches-wide shelf apparatuses.

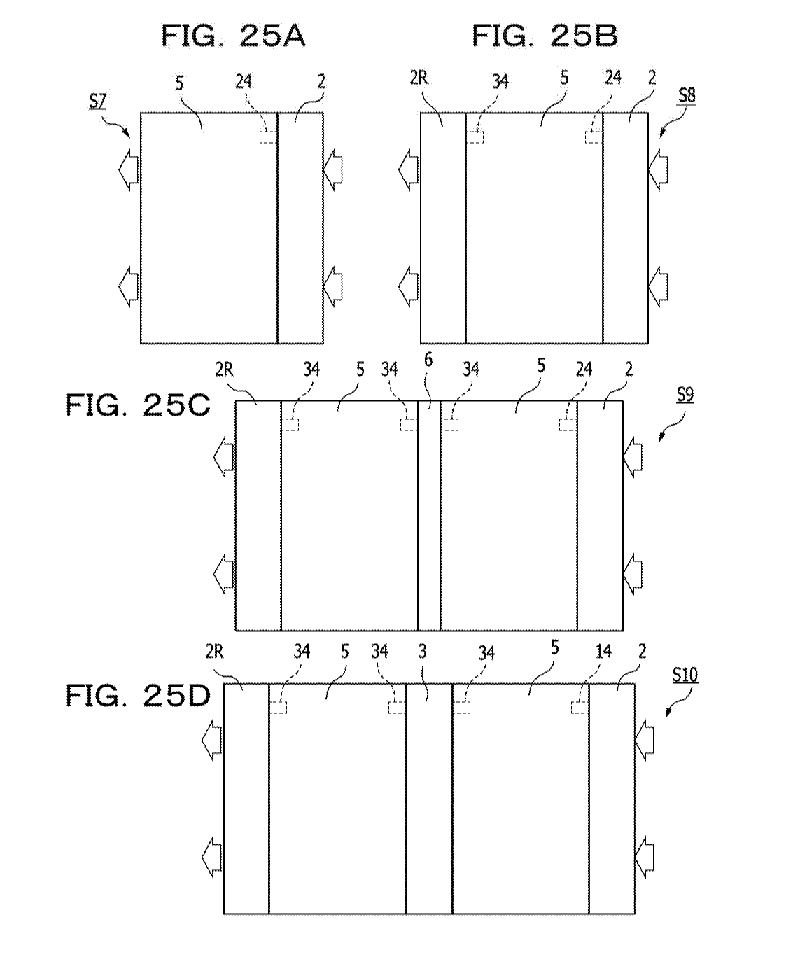

FIGS. 25A to 25D illustrate use examples of 19 inches-wide shelf apparatuses. In these examples, the second air-cooling device 2, body 5, third air-cooling device 3, joint device 6, and an inverted second air-cooling device 2R are arranged transversely. The inverted second air-cooling device 2R is obtained by installing the second air-cooling device 2 upside down. The schematic front view of FIG. 25A illustrates the shelf apparatus S7 illustrated in FIG. 24A. The schematic front view illustrated in FIG. 25B illustrates a shelf apparatus S8 of an eighth embodiment (hereinafter, just referred to as a shelf apparatus S8) in which the inverted second air-cooling device 2R is attached to the exhaust side of the shelf apparatus S7 illustrated in FIG. 25A.

The schematic front view in FIG. 25C illustrates a shelf apparatus S9 of a ninth embodiment in which another body 5 is added to the shelf apparatus S8 illustrated in FIG. 25B and is combined with the joint device 6. Moreover, the schematic front view in FIG. 25D illustrates a shelf apparatus S10 of a tenth embodiment in which another body 5 is added to the shelf apparatus S8 illustrated in FIG. 25B and is combined with the third air-cooling device 3. As described above, in regard to 19 inches-wide shelf apparatuses, the second air-cooling device 2, body 5, third air-cooling device 3, joint device 6, and second air-cooling device 2 are selectively combined to form shelf apparatuses of various specifications in response to client's requests.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A shelf apparatus comprising:
a body that includes a first opening provided in a top surface of the body, a second opening provided in a bottom surface of the body, and a back plane that is provided on a back side of the body and includes a first terminal and a second terminal, wherein at least one plug-in unit is capable of being detachably attached to the back plane;
a first air-cooling device that is attachable to the top surface of the body and includes a first substrate, a first fan coupled to the first substrate and discharges cooling wind to the back side of the body, and a first connector configured to couple the first substrate to the back plane, wherein the first terminal is coupled to the first connector inserted into the first opening;
a second air-cooling device that is attachable to the bottom surface of the body and includes a second substrate, a second fan coupled to the second substrate and sends the cooling wind toward the at least one plug-in unit, and a second connector configured to couple the second substrate to the back plane, wherein the second terminal is coupled to the second connector inserted into the second opening; and
an air guide device that is attachable to a bottom surface of the second air-cooling device and includes a baffle configured to direct the cooling wind taken in from a front side of the body toward the second air-cooling device.

2. The shelf apparatus according to claim 1,
wherein the shelf apparatus has a structure in which the air guide device is situated at the bottom and one each of the second air-cooling device, the body, and the first air-cooling device is stacked on the air guide device in this order.

3. The shelf apparatus according to claim 1,
wherein the shelf apparatus further comprises another body that is attachable to the body and includes another back plane, wherein at least one plug-in unit is capable of being detachably attached to the other back plane.

4. The shelf apparatus according to claim 3,
wherein a third connector is inserted between the body and the other body and is configured to couple the back plane with the other back plane.

5. The shelf apparatus according to claim 3,
wherein a third air-cooling device is inserted between the body and the other body, the third air-cooling device having an upper surface attachable to the bottom surface of the body and a lower surface attachable to a top surface of the other body,
wherein the third air-cooling device including
a third substrate,
a third fan coupled to the third substrate and sends the cooling wind in a direction from the lower surface to the upper surface, and
a fourth connector configured to couple the third substrate to the back plane and the other back plane.

6. The shelf apparatus according to claim 1, further comprising:
a closing plate configured to open and close the first opening; and
a lock device configured to maintain the first opening closed by the closing plate,
wherein the lock device includes:
a casing,
a slide member slidable within the casing, and
an elastic member which moves the slide member with elastic force such that an end of the slide member protrudes into the first opening.

7. The shelf apparatus according to claim 6,
wherein the closing plate is provided with a notch at a position facing the end of the slide member,
each of the first and second connectors is provided with a protrusion which is inserted into the notch before the first or second connector comes into contact with the closing plate and moves the slide member against the elastic force of the elastic member to release engagement of the end and the closing plate.

8. The shelf apparatus according to claim 6,
wherein the slide member is provided with a tapered hole at a top surface of the slide member,
a guide hole through which a slope of the tapered hole is viewable is provided at a position of the body facing the tapered hole, and
guide pins are provided on each side of the first connector of the first air-cooling device and on each side of the second connector of the second air-cooling device, each of the guide pins being inserted into the guide hole to come into contact with the slope before the first or second connector comes into contact with the closing plate and moving the slide member against the elastic force of the elastic member to release engagement of the end and the closing plate.

9. The shelf apparatus according to claim 1, further comprising:
a joint plate that is attached, and is fixed with a screw, to cover a part of at least one of boundaries between the air guide device and the second air-cooling device, between the second air-cooling device and the body, and between the body and the first air-cooling device.

10. The shelf apparatus according to claim 1, wherein the elastic member is a spring.

11. A method of manufacturing a shelf apparatus including a body, a first air-cooling device, a second air-cooling device, and an air guide device, the body including a first opening provided in a top surface of the body, a second opening provided in a bottom surface of the body, and a back plane that is provided on a back side of the body and includes a first terminal and a second terminal wherein at least one plug-in unit is capable of being detachably attached to the back plane, the first air-cooling device including a first substrate, a first fan coupled to the first substrate and discharges cooling wind to the back side of the body, and a first connector configured to couple the first substrate to the back plane, the second air-cooling device including a second substrate, a second fan coupled to the second substrate and sends the cooling wind toward the at least one plug-in unit, and a second connector configured to couple the second substrate to the back plane, and the air guide device including a baffle configured to direct the cooling wind taken in from a front side of the body toward the second air-cooling device, the method comprising:
inserting the first connector of the first air-cooling device into the first opening of the body;
coupling the first connector inserted into the first opening to the first terminal of the back plane to attach the first air-cooling device to the top surface of the body;
inserting the second connector of the second air-cooling device into the second opening of the body;
coupling the second connector inserted into the second opening to the second terminal of the back plane to attach the second air-cooling device to the bottom surface of the body; and
attaching the air guide device to a bottom surface of the second air-cooling device.
